(19) United States
(12) Patent Application Publication
(10) Pub. No.: US 2024/0407158 A1
(43) Pub. Date: Dec. 5, 2024

(54) INTEGRATED CIRCUIT DEVICE

(71) Applicant: Samsung Electronics Co., Ltd., Suwon-si (KR)

(72) Inventors: Jinseo Choi, Suwon-si (KR); Jeongmin Jin, Suwon-si (KR); Sohee Choi, Suwon-si (KR)

(21) Appl. No.: 18/638,205

(22) Filed: Apr. 17, 2024

(30) Foreign Application Priority Data
Jun. 5, 2023 (KR) 10-2023-0072346

(51) Int. Cl. H10B 12/00

(52) U.S. Cl. CPC H10B 12/50; H10B 12/09; H10B 12/315; H10B 12/482; H10B 12/485

(57) ABSTRACT

The inventive concept provides an integrated circuit device including: a substrate including a cell region and a peripheral circuit region; a plurality of bit line structures spaced apart from each other in the cell region with each bit line structure including a bit line conductive layer and a bit line capping layer on the bit line conductive layer; and a plurality of landing pads with each landing pad of the plurality of landing pads disposed on a respective bit line structure of the plurality of bit line structures and electrically connected to the substrate, wherein the peripheral circuit region includes a gate structure and a core capping layer on the gate structure; a direct contact plug extending vertically with respect to the substrate; first peripheral circuit wiring patterns extending laterally and spaced apart from each other on a first plane at a first vertical level relative to the substrate; and second peripheral circuit wiring patterns extending laterally and spaced apart from each other on a second plane at a second vertical level relative to the substrate, wherein the second vertical level is different from the first vertical level.

### CROSS-REFERENCE TO RELATED APPLICATION

This application is based on and claims priority under 35 U.S.C. § 119 to Korean Patent Application No. 10-2023-0072346, filed on Jun. 5, 2023, in the Korean Intellectual Property Office, the disclosure of which is incorporated by reference herein in its entirety.

### BACKGROUND

The inventive concept relates to an integrated circuit device, and more particularly, to an integrated circuit device including bit line peripheral (BLP) circuitry.

Recently, due to the development of electronic technology, down-scaling of integrated circuit devices is rapidly progressing, and thus feature sizes of the integrated circuit devices are miniaturized. Accordingly, it is beneficial to develop new structures that can improve electrical reliability of conductive patterns formed in a narrow area to facilitate the downscaling of integrated circuits.

### SUMMARY

The inventive concept provides integrated circuit devices that improve process margin and improve reliability.

In addition, the inventive concept is not limited to the above-mentioned integrated circuit devices, and other integrated circuit devices can be clearly understood by those skilled in the art from the description below.

In order to achieve the above-mentioned integrated circuit devices, the inventive concept provides the following integrated circuit devices.

According to an aspect of the inventive concept, there is provided an integrated circuit device including a substrate including a cell region and a peripheral circuit region, a plurality of bit line structures spaced apart from each other in the cell region with each bit line structure including a bit line conductive layer and a bit line capping layer on the bit line conductive layer, and a plurality of landing pads with each landing pad of the plurality of landing pads disposed on a respective bit line structure of the plurality of bit line structures and electrically connected to the respective bit line structure, wherein the peripheral circuit region includes a gate structure and a core capping layer on the gate structure, a direct contact plug extending vertically with respect to the substrate, first peripheral circuit wiring patterns extending laterally and spaced apart from each other on a first plane at a first vertical level relative to the substrate, and second peripheral circuit wiring patterns extending laterally and spaced apart from each other on a second plane at a second vertical level relative to the substrate, wherein the second vertical level is different from the first vertical level.

According to an aspect of the inventive concept, there is provided an integrated circuit device including a substrate including a cell region and a peripheral circuit region, a plurality of bit line structures extending parallel to each other in a first horizontal direction in the cell region, a plurality of buried contacts electrically connected to the cell region with each buried contact of the plurality of buried contacts filling a portion of a space between respective adjacent bit line structures of the plurality of bit line structures, a plurality of landing pads with each landing pad of the plurality of landing pads disposed on a respective buried contact of the plurality of buried contacts, a gate structure and a direct contact plug that are arranged in the peripheral circuit region, a first peripheral circuit wiring pattern that is at a vertical level higher relative to the substrate than an uppermost surface of the gate structure and having a plurality of first peripheral circuit wiring pattern recesses, an insulating layer filling the plurality of first peripheral circuit wiring pattern recesses and covering an upper portion of the first peripheral circuit wiring pattern, and a second peripheral circuit wiring pattern formed on the insulating layer.

According to an aspect of the inventive concept, there is provided an integrated circuit device including a substrate including a cell region having a first active region and a peripheral circuit region having a second active region, a direct contact contacting the first active region in the cell region, a bit line structure on the direct contact, a capacitor structure electrically connected to the first active region, a gate structure on the second active region in the peripheral circuit region, a first peripheral circuit wiring pattern adjacent to the gate structure and electrically connected to the second active region, a second peripheral circuit wiring pattern on the first peripheral circuit wiring pattern, a wiring insulating layer between the first peripheral circuit wiring pattern and the second peripheral circuit wiring pattern, and a contact plug penetrating the wiring insulating layer and connected to at least one of the first peripheral circuit wiring pattern and the second peripheral circuit wiring pattern, wherein the wiring insulating layer extends into the cell region, and the capacitor structure includes a dummy electrode that contacts an upper surface of the wiring insulating layer.

### BRIEF DESCRIPTION OF THE DRAWINGS

Embodiments will be more clearly understood from the following detailed description taken in conjunction with the accompanying drawings in which:

FIG. 1 is a block diagram for explaining a configuration of an integrated circuit device according to embodiments;

FIG. 2 is a plan view for explaining an arrangement of an integrated circuit device according to embodiments;

FIG. 3 is a schematic plan layout for explaining main components of a cell array region of an integrated circuit device according to embodiments; and

FIGS. 4A to 4L, 5A to 5K, 6A to 6H, and 7A to 7F are cross-sectional views shown according to process sequences for explaining methods of manufacturing an integrated circuit device, according to embodiments.

### DETAILED DESCRIPTION OF THE EMBODIMENTS

Hereinafter, preferred embodiments will be described in detail with reference to the accompanying drawings. The same reference numerals are used for the same components in the drawings, and duplicate descriptions thereof are omitted.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

Although the present embodiments may have various modifications and may have various embodiments, specific embodiments will be illustrated in the drawings and described in detail in the detailed description. However, this is not intended to limit the scope of the inventive concept to specific embodiments, and should be understood to include all modifications, equivalents, and substitutes included in the spirit and scope of the inventive concept. In describing the embodiments, if it is determined that a detailed description of a related known technology may obscure the subject matter, the detailed description will be omitted.

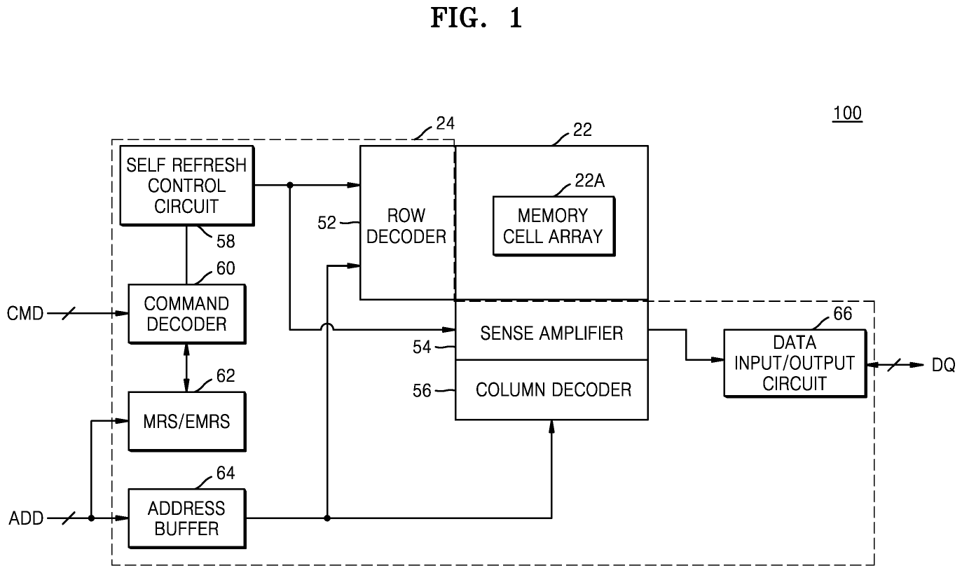

FIG. 1 is a block diagram for explaining a configuration of an integrated circuit device 100 according to embodiments.

Referring to FIG. 1, the integrated circuit device 100 may include a first region 22 and a second region 24. The first region 22 may be a memory cell region of a dynamic random access memory (DRAM) device, and the second region 24 may be a peripheral circuit region of the DRAM device. The first region 22 may include a memory cell array 22A. The second region 24 may include a row decoder 52, a sense amplifier 54, a column decoder 56, a self-refresh control circuit 58, a command decoder 60, a mode register set/extended mode register set (MRS/EMRS) circuit 62, an address buffer 64, and a data input/output circuit 66.

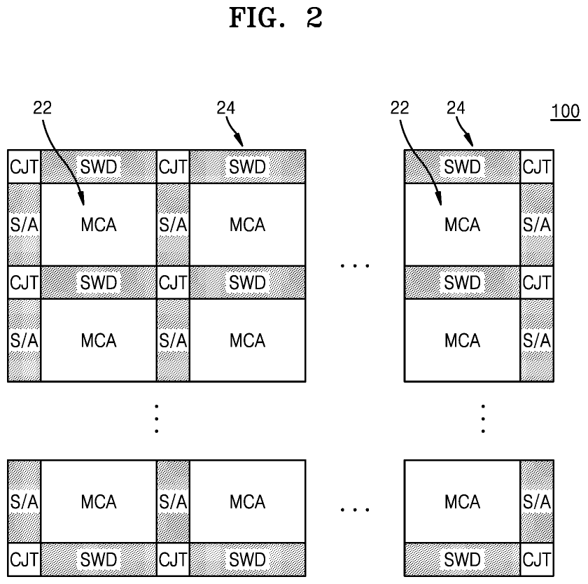

FIG. 2 is a plan view for explaining an arrangement of the integrated circuit device 100 illustrated in FIG. 1.

Referring to FIG. 2, the integrated circuit device 100 includes a plurality of first regions 22. Each of the plurality of first regions 22 may be surrounded by the second region 24.

Each of the plurality of first regions 22 may be a cell array region MCA of the DRAM device, and the second region 24 may be a region where peripheral circuits of the DRAM device are formed and a core region (hereinafter referred to as “peripheral circuit region”). The cell array region MCA in the plurality of first regions 22 may include the memory cell array 22A described with reference to FIG. 1.

The second region 24 may include a sub-word line driver block SWD, a sense amplifier block S/A, and a conjunction block CJT. A plurality of bit line sense amplifiers may be disposed in the sense amplifier block S/A. The conjunction block CJT may be disposed at a point where the sub word line driver block SWD and the sense amplifier block S/A intersect. Power drivers and ground drivers for driving the bit line sense amplifiers may be alternately arranged (e.g., alternate between a power driver and a ground driver) in the conjunction block CJT. Peripheral circuits such as an inverter chain and an input/output circuit may be further formed in the second region 24.

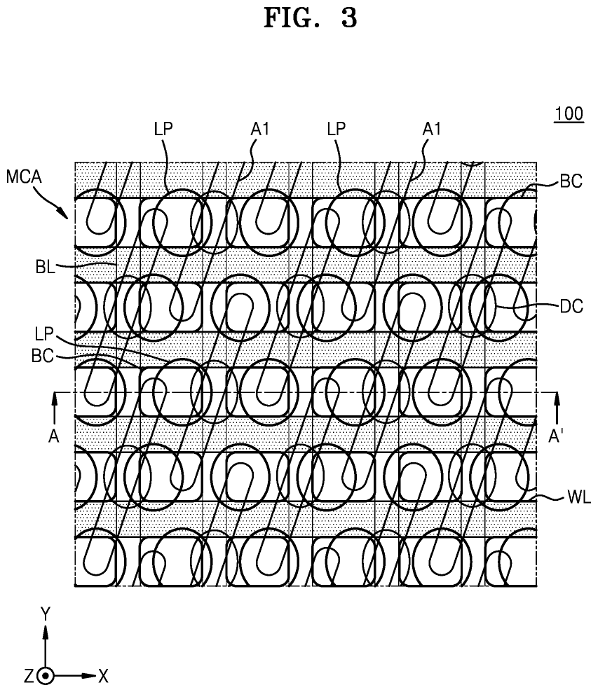

FIG. 3 is a schematic plan layout for explaining main components of the cell array region MCA illustrated in FIG. 2.

Referring to FIG. 3, the cell array region MCA may include a plurality of cell active regions A1. The plurality of cell active regions A1 may be arranged to have long axes in an oblique direction respectively with respect to a first horizontal direction (X direction) and a second horizontal direction (Y direction). A plurality of word lines WL may extend parallel to each other along the first horizontal direction (X direction) across the plurality of cell active regions A1. A plurality of bit lines BL may extend parallel to each other along the second horizontal direction (Y direction) over the plurality of word lines WL. The plurality of bit lines BL may be connected to the plurality of cell active regions A1 through direct contacts DC. A plurality of buried contacts BC may be formed between two adjacent bit lines BL among the plurality of bit lines BL. The plurality of buried contacts BC may be arranged in a line along the first horizontal direction (X direction) and the second horizontal direction (Y direction). A plurality of conductive landing pads LP may be formed on the plurality of buried contacts BC. The plurality of buried contacts BC and the plurality of conductive landing pads LP may serve to connect a lower electrode (not shown) of a capacitor formed over the plurality of bit lines BL to the cell active region A1. The capacitor may include a capacitor dielectric layer. The capacitor dielectric layer may be interposed between the lower electrode and the upper electrode. The capacitor dielectric layer, the lower electrode, and the upper electrode may constitute a capacitor structure. Each of the plurality of conductive landing pads LP may be arranged to partially overlap the buried contact BC. A conductive landing pad LP may be electrically connected to a bit line structure and a buried contact. The conductive landing pad may have a lateral dimension (e.g., a diameter in the X-Y plane) that is greater than a width of a bit line structure and/or the buried contact BC. An upper surface of the landing pad LP may be planar in a horizontal plane.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The plurality of conductive landing pads LP illustrated in FIG. 3 may be formed through a series of processes including a plurality of exposure processes. In some embodiments, the series of processes for forming the plurality of conductive landing pads LP may include a photolithography process using extreme ultraviolet (EUV).

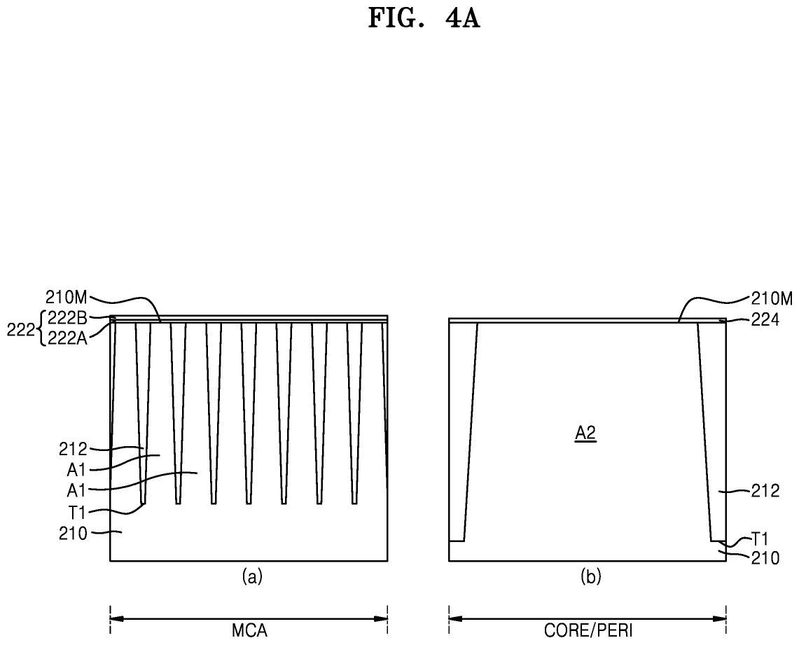

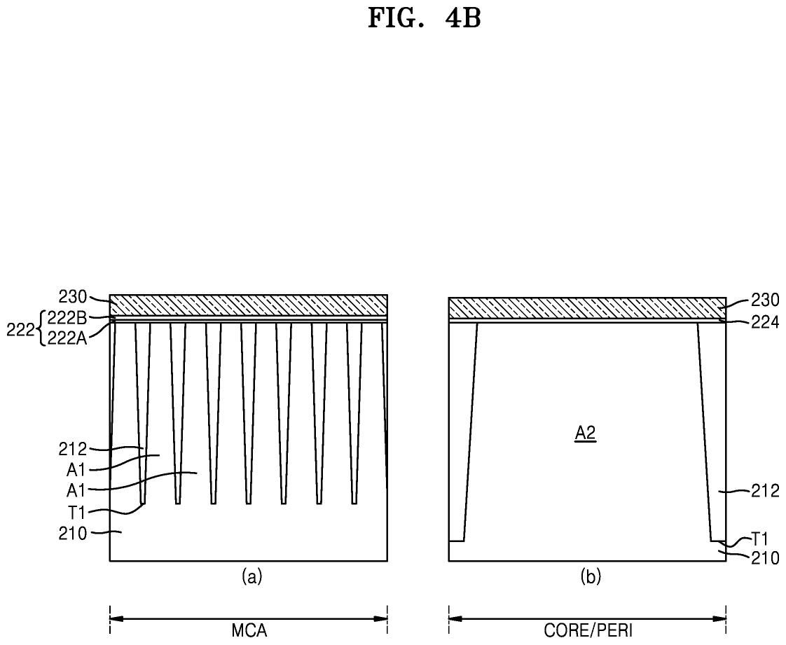

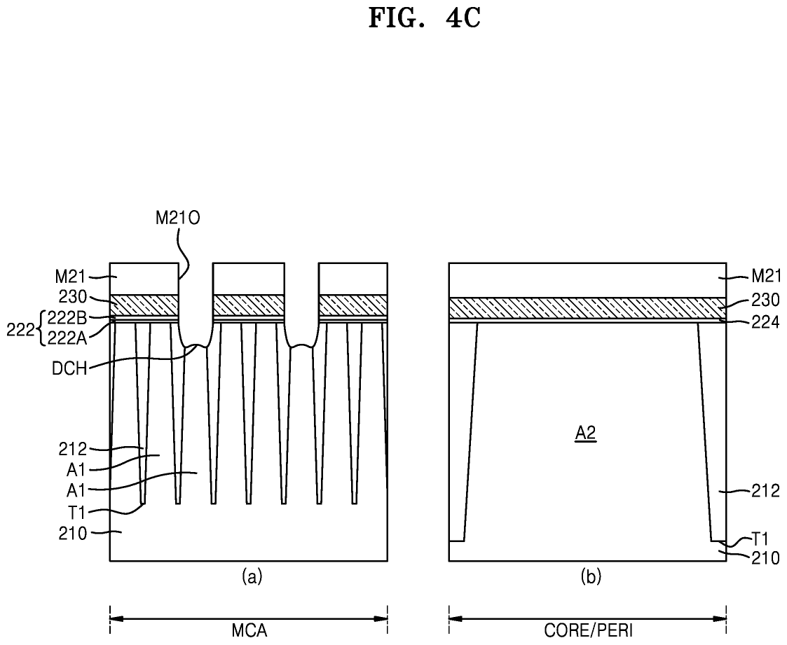

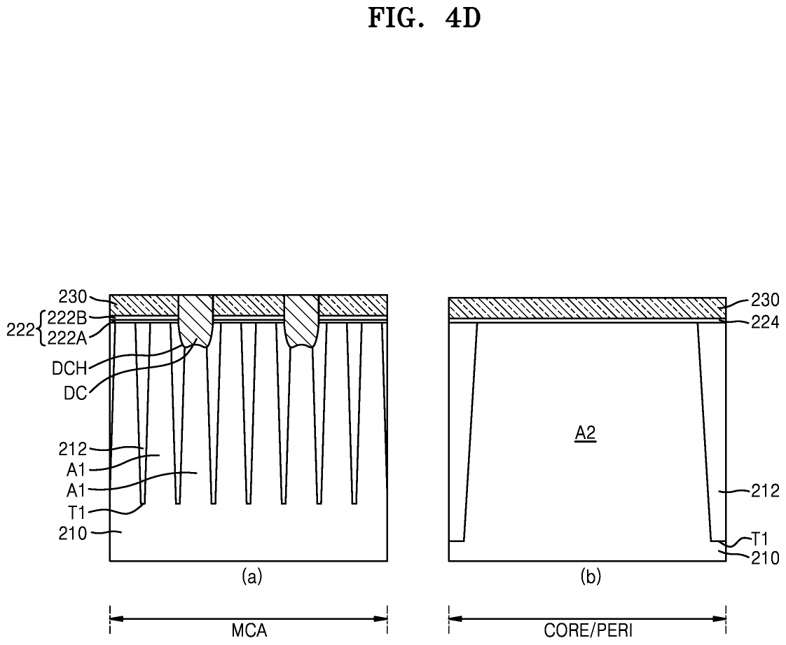

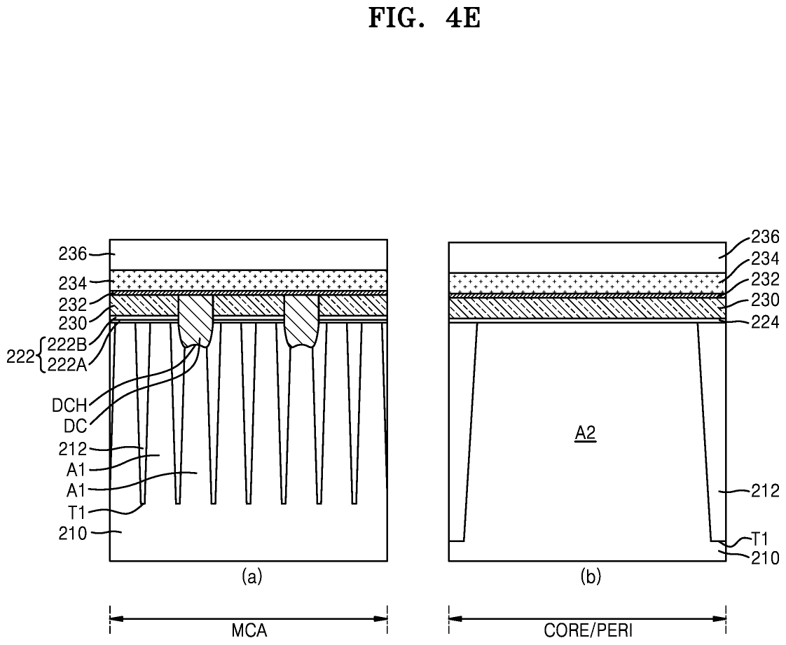

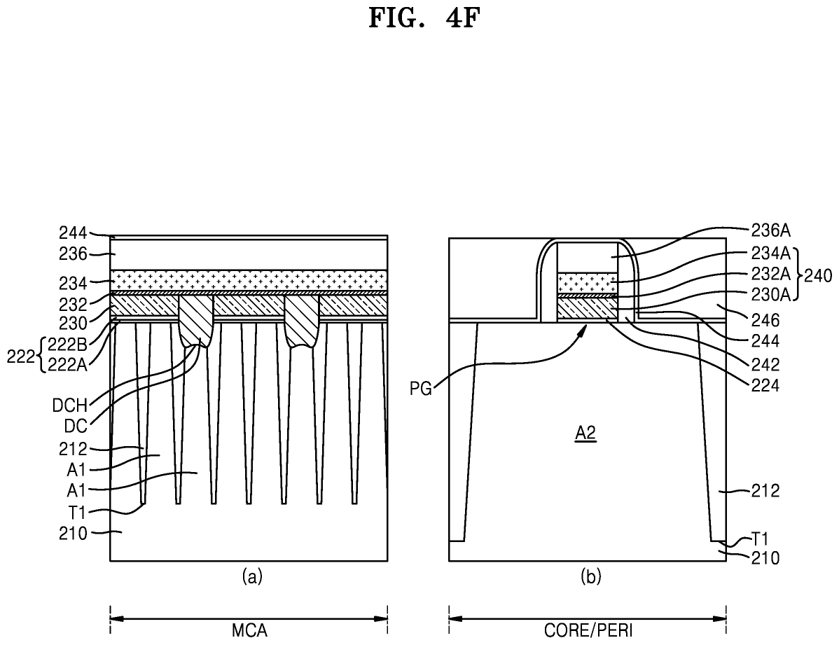

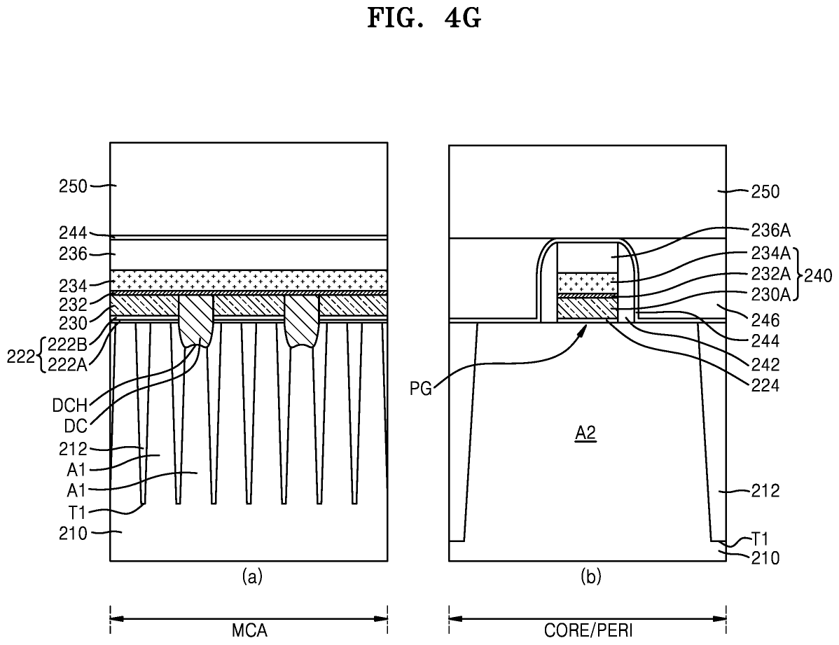

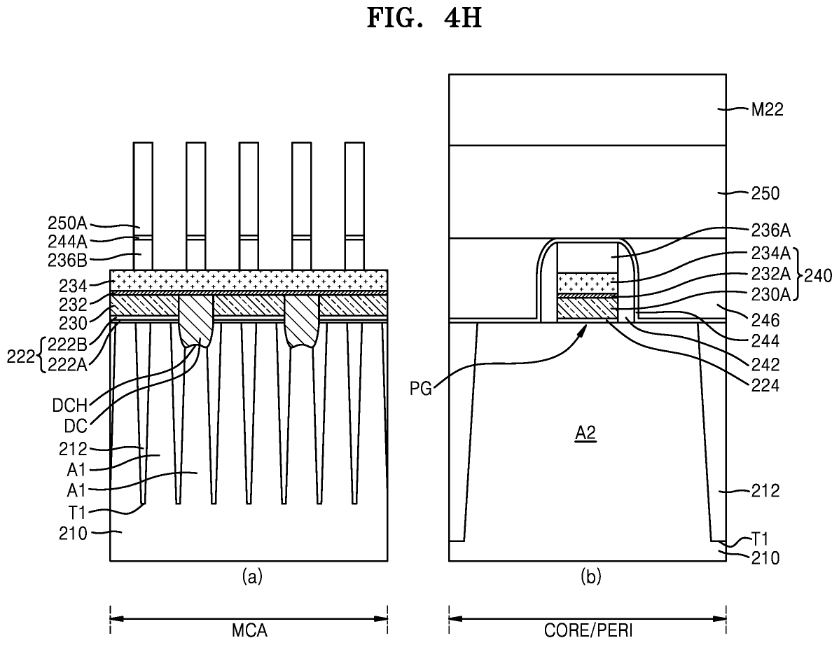

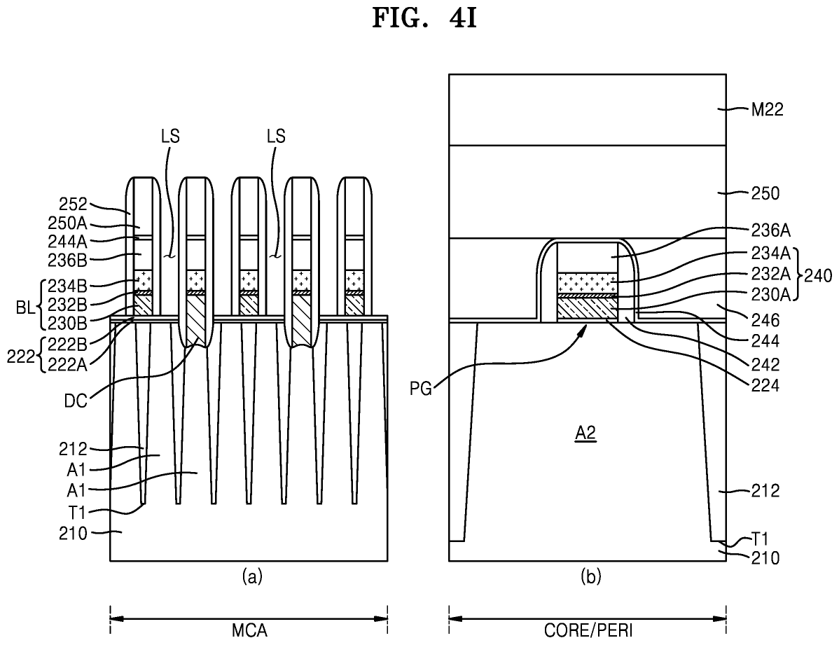

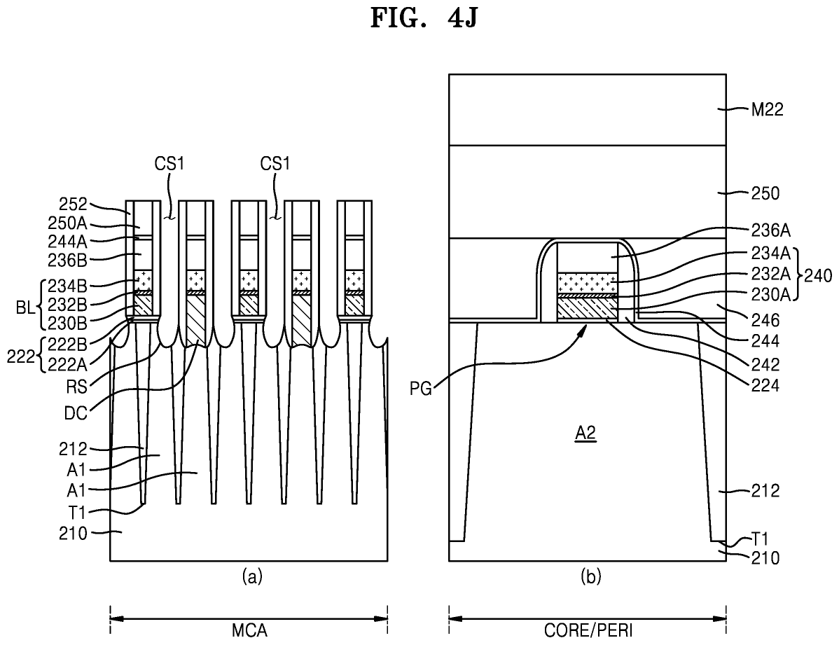

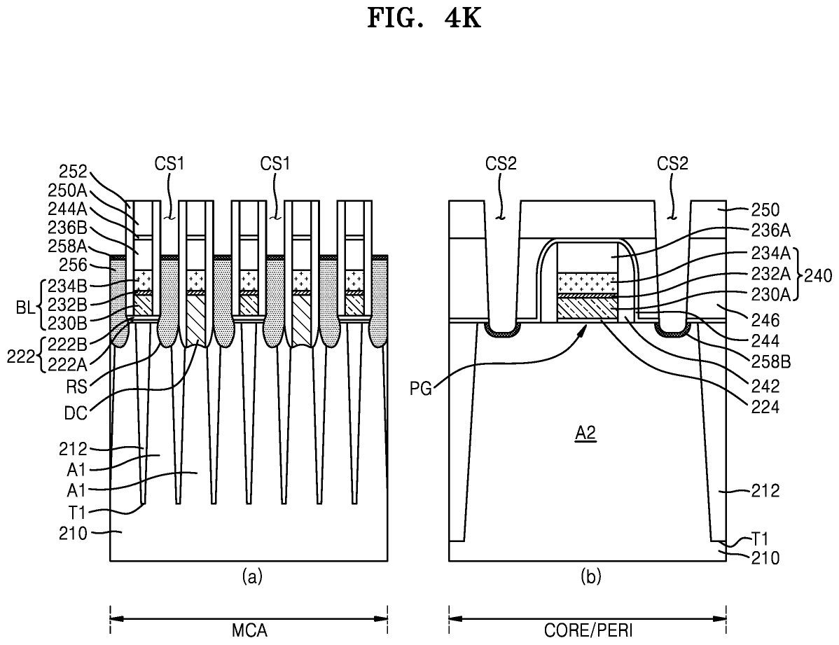

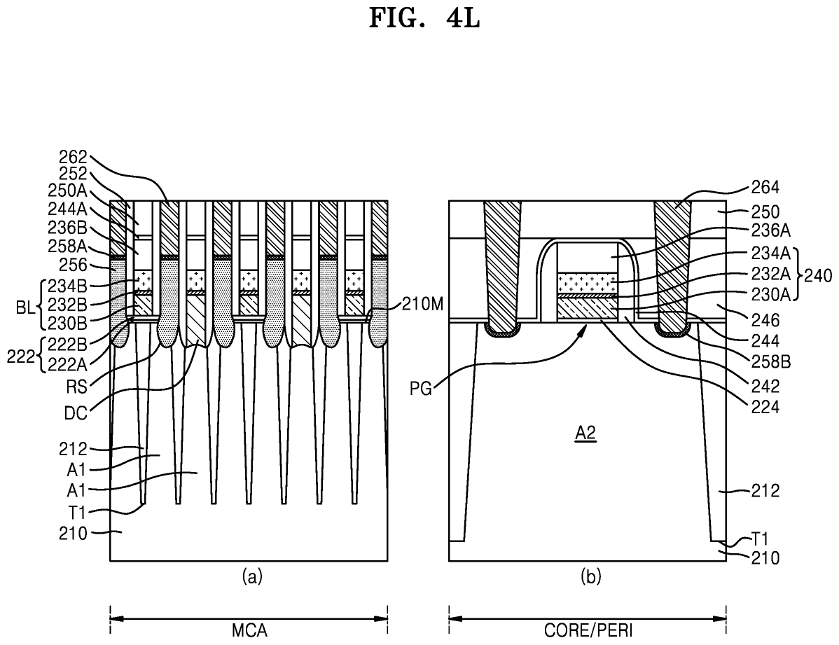

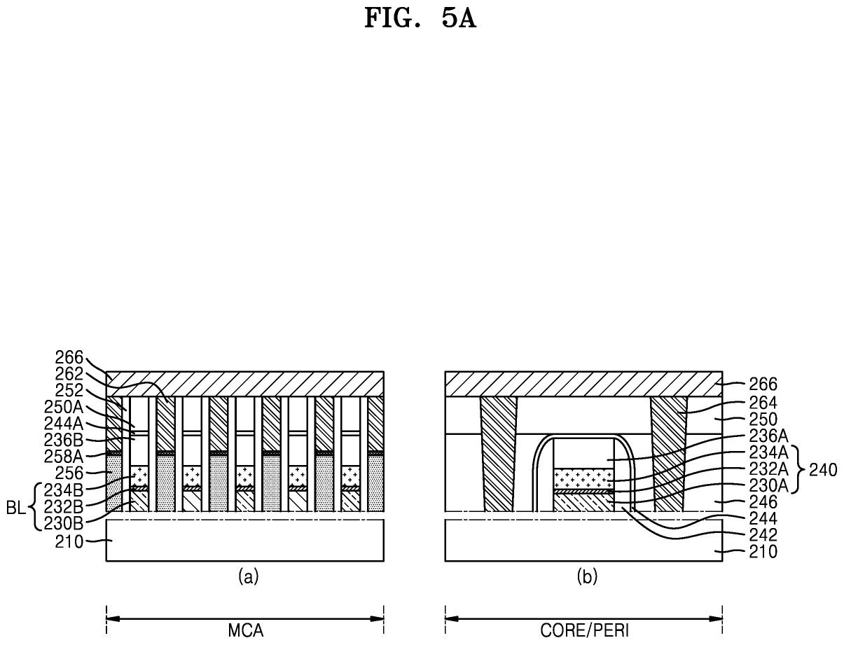

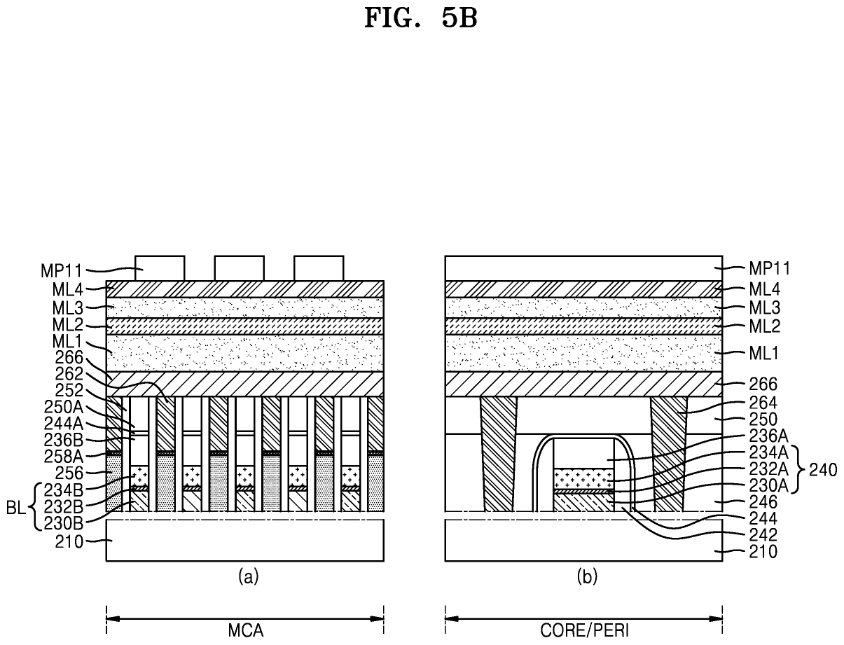

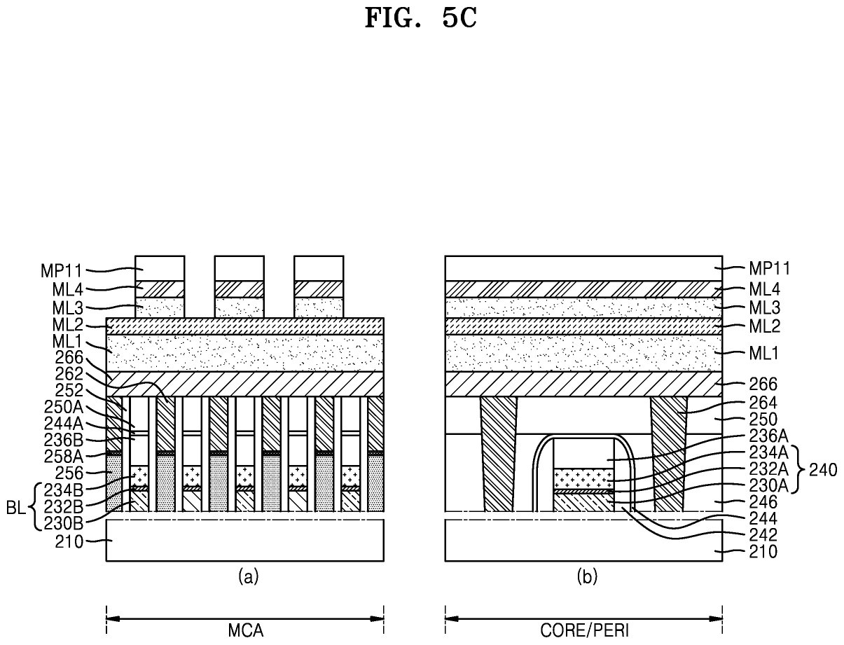

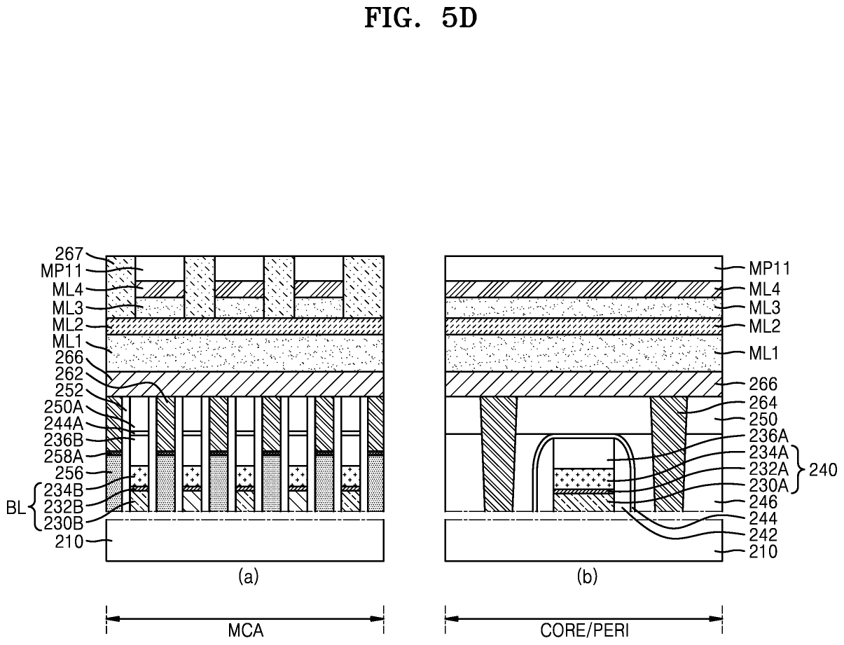

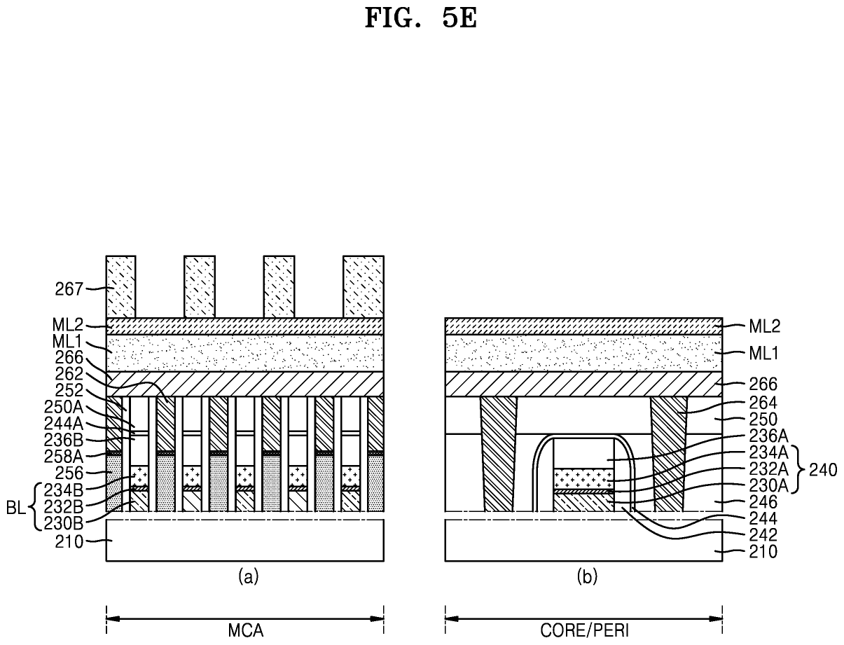

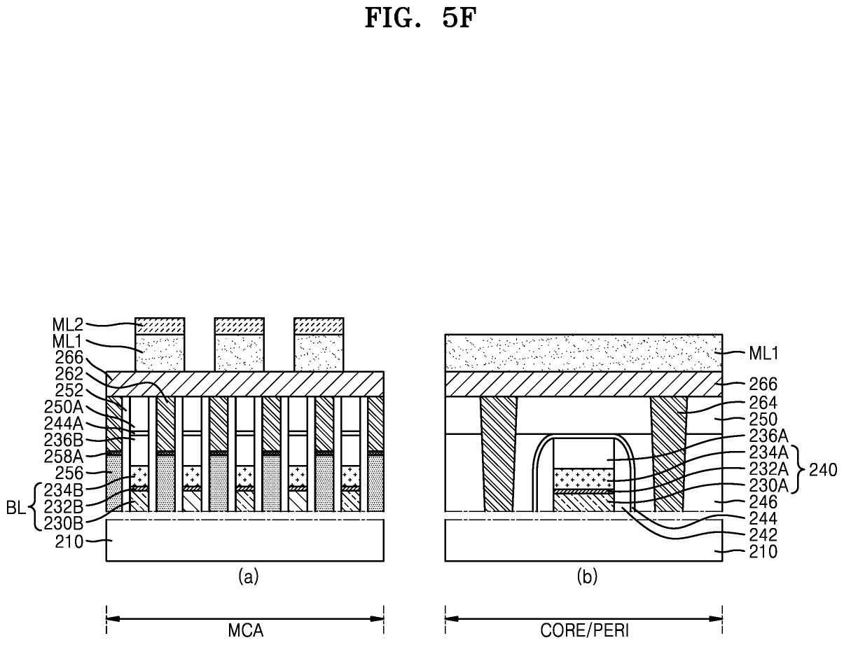

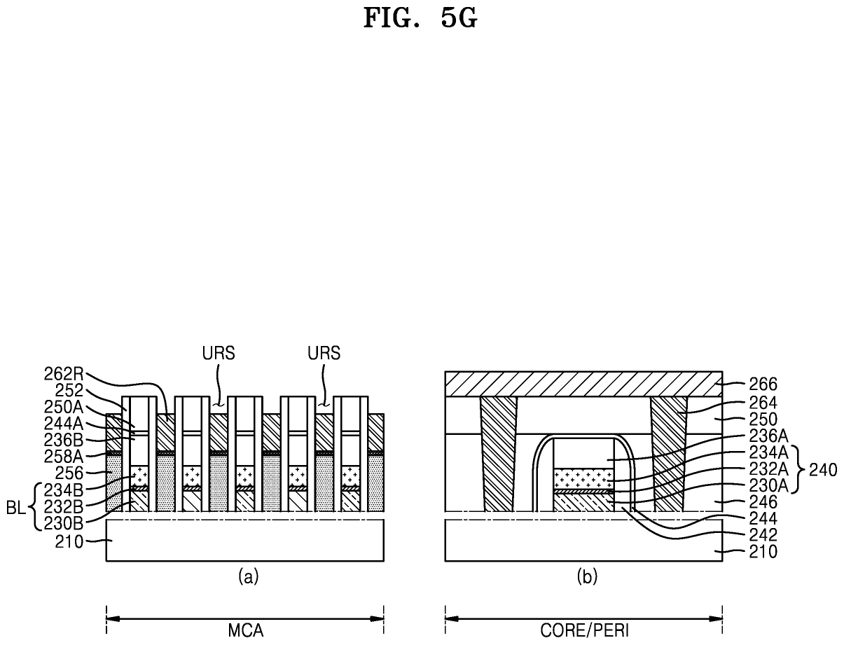

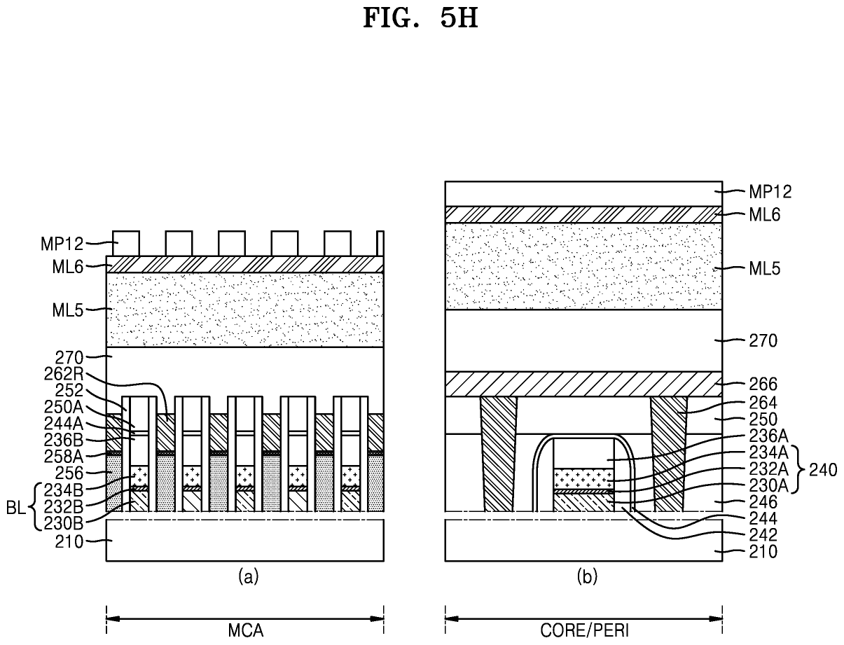

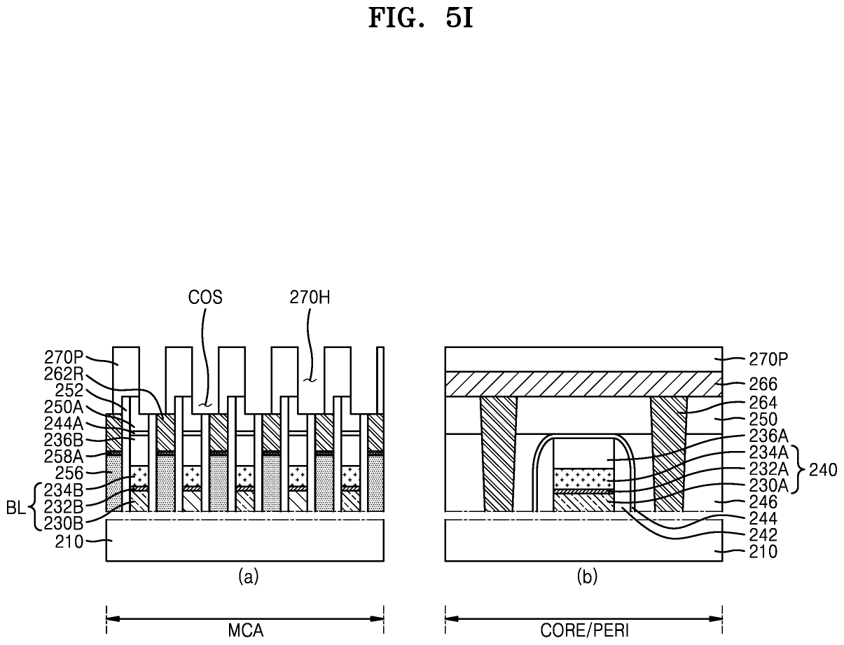

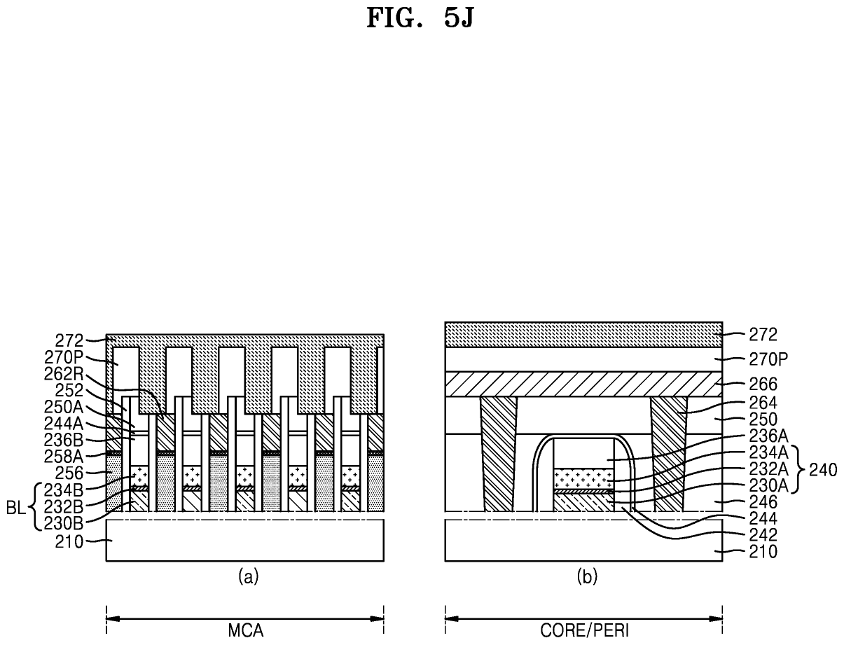

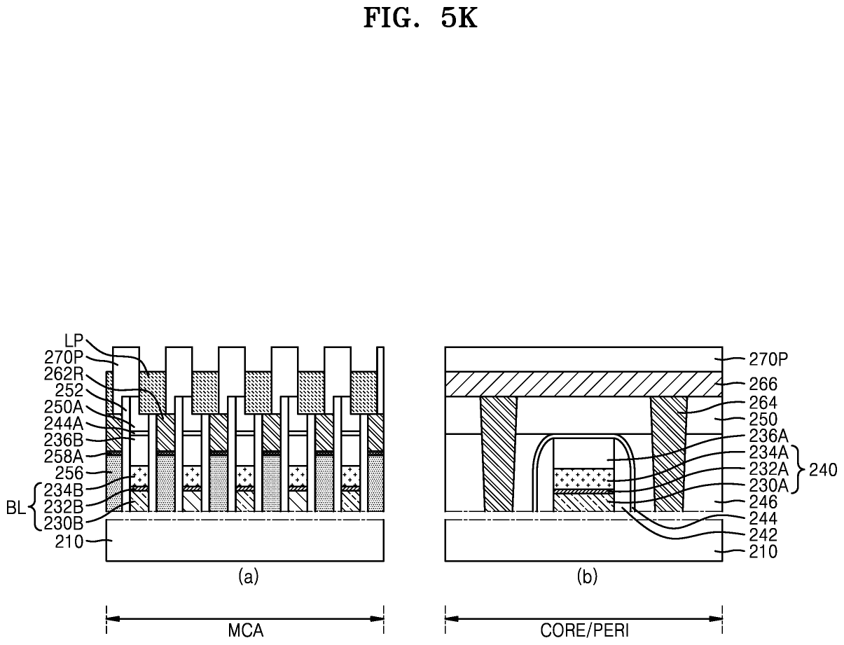

FIGS. 4A to 4L, 5A to 5K, 6A to 6H, and 7A to 7F are cross-sectional views according to process sequences for explaining methods of manufacturing an integrated circuit device, according to embodiments. More specifically, in FIGS. 4A to 4L, 5A to 5K, 6A to 6H, and 7A to 7F, (a) is a cross-sectional view of some regions of the cell array region MCA taken along a line A-A′ of FIG. 3 according to a process sequence, and (b) is a cross-sectional view of some components of a peripheral circuit region CORE/PERI according to the process sequence. In FIGS. 5A to 5K, 6A to 6H, and 7A to 7F, some components illustrated in FIG. 4L are omitted for convenience of illustration.

First, with reference to FIGS. 4A to 4L, methods of manufacturing an integrated circuit device, according to the inventive concept will be described in sequence with specific examples.

Referring to FIG. 4A, a plurality of device isolation trenches Tl and a plurality of device isolation layers 212 may be formed in a substrate 210 having the cell array region MCA and the peripheral circuit region CORE/PERI, to define a plurality of cell active regions A1 in the cell array region MCA of the substrate 210 and define a peripheral active region A2 in the peripheral circuit region CORE/PERI.

After forming a plurality of word line trenches (not shown) extending in parallel to each other in the substrate 210 in the cell array region MCA, a plurality of gate dielectric layers, a plurality of word lines, and a plurality of buried insulating layers may be sequentially formed in the plurality of word line trenches. The plurality of word lines may constitute the plurality of word lines WL illustrated in FIG. 3. A plurality of source/drain regions may be formed on the plurality of cell active regions A1 by implanting impurity ions into portions on both sides of the plurality of word lines WL in the plurality of cell active regions A1. In embodiments, the plurality of source/drain regions may be formed before forming the plurality of word lines WL.

Thereafter, a buffer layer 222 may be formed on a main surface 210M of the substrate 210 in the cell array region MCA, and a gate dielectric layer 224 may be formed on the main surface 210M of the substrate 210 in the peripheral circuit region CORE/PERI. The buffer layer 222 may include a first insulating layer 222A and a second insulating layer 222B. Each of the first insulating layer 222A and the second insulating layer 222B may be formed of and/or include an oxide layer, a nitride layer, or a combination thereof.

Referring to FIG. 4B, a lower conductive layer 230 may be formed on the buffer layer 222 in the cell array region MCA and the gate dielectric layer 224 in the peripheral circuit region CORE/PERI. The lower conductive layer 230 may be formed of and/or include doped polysilicon.

Referring to FIG. 4C, after a mask pattern M21 is formed on the lower conductive layer 230 in the cell array region MCA and the peripheral circuit region CORE/PERI, the lower conductive layer 230 exposed through an opening M210 of the mask pattern M21 may be etched, and then a portion of the substrate 210 and a portion of the device isolation layer 212 exposed by the resultant of etching may be etched to form a direct contact hole DCH that exposes the cell active region A1 of the substrate 210. The mask pattern M21 may include an oxide layer, a nitride layer, or a combination thereof.

Referring to FIG. 4D, the mask pattern M21 may be removed from the resultant of FIG. 4C, and then a direct contact DC may be formed in the direct contact hole DCH in the cell array region MCA. In a process for forming the direct contact DC, a conductive layer having a sufficient thickness to fill the direct contact hole DCH is formed on top of the lower conductive layer 230, and then the conductive layer may be etched back so that the conductive layer remains only within the direct contact hole DCH. The conductive layer may be formed of and/or include doped polysilicon, Ge, W, WN, Co, Ni, Al, Mo, Ru, Ti, TiN, Ta, TaN, Cu, or combinations thereof.

Referring to FIG. 4E, an intermediate conductive layer 232, an upper conductive layer 234, and a lower insulating capping layer 236 may be sequentially formed on the lower conductive layer 230 and the direct contact DC in the cell array region MCA and the peripheral circuit region CORE/PERI.

The intermediate conductive layer 232 and the upper conductive layer 234 may each include TIN, TiSiN, W, tungsten silicide, or a combination thereof. The lower insulating capping layer 236 may include a silicon nitride layer. In embodiments, the intermediate conductive layer 232 may be formed of and/or include TIN, TiSiN, or a combination thereof, and the upper conductive layer 234 may be formed of and/or include W. The lower insulating capping layer 236 may include a silicon nitride layer.

Referring to FIG. 4F, in the resultant of FIG. 4E, in a state in which the cell array region MCA is covered with a mask pattern (not shown), using a mask pattern (not shown) formed on the peripheral circuit region CORE/PERI, the lower insulating capping layer 236, the upper conductive layer 234, the intermediate conductive layer 232, the lower conductive layer 230, and the gate dielectric layer 224 may be patterned to form a gate electrode 240 formed on the gate dielectric layer 224 and a gate capping pattern 236A covering the gate electrode 240, in which the gate electrode 240 may include a lower conductive pattern 230A, an intermediate conductive pattern 232A, and an upper conductive pattern 234A. The gate dielectric layer 224, the gate electrode 240, and the gate capping pattern 236A may form a gate structure PG and may be stacked such that the gate structure PG may be a stacked structure. Thereafter, insulating spacers 242 may be formed on both sidewalls of the gate structure PG and then source/drain regions (not shown) may be formed in a peripheral active region A2 below both sides of the gate structure PG by performing an ion implantation process. In embodiments, the insulating spacer 242 may be formed of and/or include an oxide layer, a nitride layer, or a combination thereof.

Thereafter, the mask pattern covering the cell array region MCA may be removed to expose the lower insulating capping layer 236 in the cell array region MCA, and then an insulating thin layer 244 may be formed to cover the entire surface of the exposed cell array region MCA and exposed peripheral circuit region CORE/PERI. Thereafter, an interlayer insulating layer 246 may be formed to fill a space around the gate structure PG in the peripheral circuit region CORE/PERI. The insulating thin layer 244 may be formed of and/or include a silicon nitride layer. The interlayer insulating layer 246 may include a polysilazane film such as polyperhydrosilazane which is commercially available as Tonen SilaZene® (TOSZ), but embodiments are not limited thereto.

Referring to FIG. 4G, an upper insulating capping layer 250 may be formed on the insulating thin layer 244 in the cell array region MCA and the interlayer insulating layer 246 in the peripheral circuit region CORE/PERI. The upper insulating capping layer 250 may include a silicon nitride layer.

Referring to FIG. 4H, in a state in which the upper insulating capping layer 250 is covered with a mask pattern M22 in the peripheral circuit region CORE/PERI, the upper insulating capping layer 250, the insulating thin layer 244, and the lower insulating capping layer 236 may be patterned in the cell array region MCA by using a photolithography process, so that a lower insulating capping pattern 236B, an insulating thin layer pattern 244A, and an upper insulating capping pattern 250A may be sequentially stacked on the upper conductive layer 234.

Referring to FIG. 4I, in a state in which the upper insulating capping layer 250 is covered with the mask pattern M22 in the peripheral circuit region CORE/PERI, in the cell array region MCA, the upper conductive layer 234, the intermediate conductive layer 232, and the lower conductive layer 230 may be etched using the lower insulating capping pattern 236B, the insulating thin layer pattern 244A, and the upper insulating capping pattern 250A as an etch mask, thereby forming a plurality of bit lines BL including a lower conductive pattern 230B, an intermediate conductive pattern 232B, and an upper conductive pattern 234B.

The lower insulating capping pattern 236B, the insulating thin layer pattern 244A, and the upper insulating capping pattern 250A may form an insulating capping structure. Thereafter, a plurality of insulating spacers 252 may be formed on both sidewalls of the insulating capping structure and on both sidewalls of the bit line BL. The plurality of insulating spacers 252 may be formed to fill the direct contact hole DCH around the direct contact DC. After the plurality of insulating spacers 252 are formed, a line space LS may remain between the plurality of bit lines BL. The height of the upper insulating capping pattern 250A may be decreased by etching processes performed while forming the plurality of bit lines BL and the plurality of insulating spacers 252.

Referring to FIG. 4J, in a state in which the upper insulating capping layer 250 is covered with the mask pattern M22 in the peripheral circuit region CORE/PERI, a plurality of insulating fences (not shown) may be formed between the plurality of bit lines BL in the cell array region MCA. As a result, one line space LS may be isolated into a plurality of contact spaces CS1 having a columnar shape. A width of the plurality of contact spaces CS1 in a horizontal direction may be limited by each of the plurality of insulating spacers 252 and the plurality of insulating fences. As the upper insulating capping pattern 250A and the insulating spacer 252 are exposed to the etching atmosphere during the formation of the plurality of insulating fences, the upper insulating capping pattern 250A and the insulating spacer 252 may be consumed and thus, a height of the upper insulating capping pattern 250A and a width of the insulating spacer 252 may be decreased.

Thereafter, by removing a portion of the buffer layer 222 exposed through the plurality of contact spaces CS1 and a portion of the exposed substrate 210, a plurality of recess spaces RS may be formed to expose the cell active region A1 of the substrate 210 between the plurality of bit lines BL.

A “trough,” “recess,” “recess space,” and “contact space,” as used herein, exists whether it remains empty or is subsequently filled with another material. For example, the plurality of recess spaces RS of FIG. 4J remain recess spaces RS after being filled with a lower contact plug 256 as shown in FIG. 4K.

Referring to FIG. 4K, in a state in which the upper insulating capping layer 250 is covered with the mask pattern M22 in the peripheral circuit region CORE/PERI as in the resultant of FIG. 4J, a plurality of lower contact plugs 256 filling a portion of the contact space CS1 between the plurality of bit lines BL while filling the plurality of recess spaces RS between the plurality of the bit lines BL may be formed. The plurality of lower contact plugs 256 may be formed of and/or include doped polysilicon.

Thereafter, after the mask pattern M22 is removed from the peripheral circuit region CORE/PERI to expose the upper insulating capping layer 250, in a state in which a mask pattern (not shown) is formed to cover the cell array region MCA, a plurality of contact spaces CS2 that exposes the peripheral active region A2 of the substrate 210 may be formed by etching some of the upper insulating capping layer 250, the interlayer insulating layer 246, and the insulating thin layer 244 in the peripheral circuit region CORE/PERI.

After removing the mask pattern (not shown) covering the cell array region MCA, a metal silicide layer 258A may be formed on the lower contact plug 256 exposed through the plurality of contact spaces CS1 in the cell array region MCA and a metal silicide layer 258B may be formed on a surface of the peripheral active region A2 exposed through the plurality of contact spaces CS2 in the peripheral circuit region CORE/PERI. The metal silicide layers 258A and 258B may be formed simultaneously or in separate processes. The metal silicide layers 258A and 258B may be formed of and/or include cobalt silicide, nickel silicide, or manganese silicide, respectively, but embodiments are not limited thereto. In embodiments, a process of forming the metal silicide layers 258A and 258B may be omitted.

Referring to FIG. 4L, from the resultant of FIG. 4K, a plurality of first contact plugs 262 may be formed to fill the plurality of contact spaces CS1 remaining on the metal silicide layer 258A in the resulting cell array region MCA, and a plurality of second contact plugs 264 may be formed to fill the plurality of contact spaces CS2 in the peripheral circuit region CORE/PERI. Herein, the plurality of first contact plugs 262 and/or the plurality of second contact plugs 264 maybe referred to as a plurality of direct contact plugs and first or second contact plug of the plurality of first contact plugs or the plurality of second contact plugs may be referred to individually as a direct contact plug. In embodiments, a process of forming the plurality of first contact plugs 262 and a process of forming the plurality of second contact plugs 264 may be performed simultaneously. In embodiments, forming the plurality of first contact plugs 262 and the plurality of second contact plugs 264 may be performed in the same process.

The bit line BL, the lower insulating capping pattern 236B, the insulating thin layer pattern 244A, the upper insulating capping pattern 250A, and a pair of insulating spacers 252 covering respective sidewalls thereof may constitute a bit line structure in the cell array region MCA. In the cell array region MCA, each of the plurality of first contact plugs 262 may be arranged between adjacent bit line structures of the plurality of bit line structures on the substrate 210. In the peripheral circuit region CORE/PERI, the plurality of second contact plugs 264 may be electrically connected to source/drain regions formed on the substrate 210, respectively.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Each of the plurality of first contact plugs 262 and the plurality of second contact plugs 264 may be formed of and/or include metal, conductive metal nitride, or a combination thereof. In embodiments, each of the plurality of first contact plugs 262 and the plurality of second contact plugs 264 may be formed of and/or include TIN, W, or a combination thereof. In one embodiment, each of the plurality of first contact plugs 262 and the plurality of second contact plugs 264 may include only a TiN layer. In another embodiment, the plurality of first contact plugs 262 and the plurality of second contact plugs 264 may each have a stacked structure of a TiN barrier layer and a W layer.

Upper surfaces of each of the plurality of first contact plugs 262, the plurality of upper insulating capping patterns 250A, and the plurality of insulating spacers 252 in the cell array region MCA may be planarized to extend on the same plane. Upper surfaces of each of the plurality of second contact plugs 264 and the upper insulating capping layer 250 in the peripheral circuit region CORE/PERI may be planarized to extend on the same plane. In embodiments, after the plurality of first contact plugs 262 and the plurality of second contact plugs 264 are formed, upper surfaces of each of the plurality of first contact plugs 262, the plurality of second contact plugs 264, and the upper insulating capping pattern 250A and the insulating spacer 252 of the plurality of bit line structures may be at the same vertical level. The term “vertical level” used herein means a distance from the main surface 210M of the substrate 210 in a direction perpendicular thereto.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Next, with reference to FIGS. 5A to 5K, methods of manufacturing an integrated circuit device, according to the inventive concept will be described in sequence with specific examples.

Referring to FIG. 5A, from the resultant of FIG. 4L, a first conductive layer 266 may be formed in the cell array region MCA and the peripheral circuit region CORE/PERI. The first conductive layer 266 may be formed to cover the plurality of first contact plugs 262 in the cell array region MCA and to cover the plurality of second contact plugs 264 in the peripheral circuit region CORE/PERI.

The first conductive layer 266 may be formed of and/or include metal, conductive metal nitride, or a combination thereof. In embodiments, the first conductive layer 266 may be formed of and/or include TIN, W, or a combination thereof. In an example, the first conductive layer 266 may include only a TiN layer. In another example, the first conductive layer 266 may include a stacked structure of a TiN barrier layer and a W layer.

Referring to FIG. 5B, a first mask layer ML1, a second mask layer ML2, a third mask layer ML3, a fourth mask layer ML4, and a photoresist pattern MP11 covering the fourth mask layer ML4 that sequentially cover the first conductive layer 266 may be formed in the cell array region MCA and the peripheral circuit region CORE/PERI. Although a total of four mask layers ML1, ML2, ML3, and ML4 are used in FIG. 5B, the number of mask layers is not limited thereto.

In embodiments, the first mask layer ML1 may include an amorphous carbon layer (ACL), the second mask layer ML2 may include a polysilicon layer, the third mask layer ML3 may include an SOH layer, and the fourth mask layer ML4 may include a SiON layer, but embodiments are not limited thereto. The photoresist pattern MP11 may be obtained from a resist layer for extreme ultraviolet (EUV), a resist layer for a KrF excimer laser, a resist layer for an ArF excimer laser, or a resist layer for an F2 excimer laser.

In embodiments, the photoresist pattern MP11 may be obtained from the resist layer for EUV. For example, in a state in which the resist layer for EUV is exposed in the cell array region MCA and the peripheral circuit region CORE/PERI, the photoresist pattern MP11 may be formed by exposing the resist layer for EUV with an EUV light source and developing the exposed resist layer for EUV only in the cell array region MCA among the cell array region MCA and the peripheral circuit region CORE/PERI.

Referring to FIG. 5C, in the resultant of FIG. 5B, the fourth mask layer ML4 and the third mask layer ML3 may be sequentially etched using the photoresist pattern MP11 as an etch mask.

Referring to FIG. 5D, an oxide layer 267 filling spaces between each of the third mask layer ML3, the fourth mask layer ML4, and the photoresist pattern MP11 remaining unetched in the cell array region MCA may be formed and then an etch-back process may be performed. As a result, the height of an uppermost surface of the oxide layer 267 and the height of an uppermost surface of the photoresist pattern MP11 may be at the same vertical level.

Referring to FIG. 5E, the third mask layer ML3, the fourth mask layer ML4, and the photoresist pattern MP11 remaining in the cell array region MCA of FIG. 5D may be removed through a strip process, and then a portion of the first mask layer ML1 and a portion of the second mask layer ML2 may be also etched using the oxide layer 267 as an etch mask in the cell array region MCA and thus the resultant of FIG. 5F may be obtained.

Referring to FIG. 5G, in the resultant of FIG. 5F, the first conductive layer 266 exposed in the cell array region MCA may be removed to expose upper surfaces of the plurality of first contact plugs 262 and the plurality of upper insulating capping patterns 250A. Thereafter, a plurality of first recess contact plugs 262R may be formed from the plurality of first contact plugs 262 by removing portions of each of the plurality of first contact plugs 262. As a result, a plurality of recess spaces URS may be formed on the first recess contact plugs 262R between each of the plurality of upper insulating capping patterns 250A included in the plurality of bit line structures. After forming the plurality of first recess contact plugs 262R, a vertical level of an uppermost surface of each of the plurality of first recess contact plugs 262R may be lower from the substrate 210 than a vertical level of an uppermost surface of each of the plurality of bit lines BL. Herein, each of the plurality of first recess contact plugs 262R may be referred to as a recess contact plug.

After the plurality of first recess contact plugs 262R and the plurality of recess spaces URS are formed in the cell array region MCA, the first mask layer ML1 may be removed to expose an upper surface of the first conductive layer 266 in the peripheral circuit region CORE/PERI.

Referring to FIG. 5H, an insulating layer 270 may be formed to cover the resultant of FIG. 5G in the cell array region MCA and the peripheral circuit region CORE/PERI, and then a fifth mask layer ML5 and a sixth mask layer ML6 made of different materials may be formed on the insulating layer 270 and a photoresist pattern MP12 may be formed on the sixth mask layer ML6.

In embodiments, the insulating layer 270 may include a silicon nitride layer, but is not limited thereto. The fifth mask layer ML5 may include an ACL, but is not limited thereto. The sixth mask layer ML6 may include a SiON layer, but is not limited thereto.

The photoresist pattern MP12 may be obtained from a resist layer for EUV, a resist layer for KrF excimer laser, a resist layer for ArF excimer laser, or a resist layer for F2 excimer laser. In embodiments, the photoresist pattern MP12 may be obtained from the resist layer for EUV. The photoresist pattern MP12 may be formed through a process similar to that described with respect to the process of forming the photoresist pattern MP22 with reference to FIG. 5B. However, in a state in which the resist layer for EUV is exposed in the cell array region MCA and the peripheral circuit region CORE/PERI, the photoresist pattern MP12 may be formed by exposing the resist layer for EUV with an EUV light source and developing the exposed resist layer for EUV only in the cell array region MCA among the cell array region MCA and the peripheral circuit region CORE/PERI.

Referring to FIG. 5I, in the resultant of FIG. 5H, the sixth mask layer ML6 and the fifth mask layer ML5 may be sequentially etched using the photoresist pattern MP12 as an etch mask, and then using the result obtained as an etch mask, the insulating layer 270 may be patterned to form an intaglio insulating pattern 270P. Thereafter, unnecessary layers on the intaglio insulating pattern 270P may be removed to expose an upper surface of the intaglio insulating pattern 270P.

The intaglio insulating pattern 270P may be arranged on the plurality of bit line structures and the plurality of first recess contact plugs 262R in the cell array region MCA, and may be formed to have a plurality of openings 270H disposed at positions shifted in a horizontal direction from the plurality of first recess contact plugs 262R.

Referring to FIG. 5J, a second conductive layer 272 may be formed on the resultant of FIG. 5I. The second conductive layer 272 may be formed to contact each upper surface of the plurality of first recess contact plugs 262R while filling the plurality of recess spaces URS (see FIG. 5G) and a plurality of cutoff spaces COS (see FIG. 5I) in the cell array region MCA.

The second conductive layer 272 may be formed of and/or include metal, conductive metal nitride, or a combination thereof. In embodiments, the second conductive layer 272 may be formed of and/or include TIN, W, or a combination thereof. In an example, the second conductive layer 272 may include only a TiN layer. In another example, the second conductive layer 272 may include a stacked structure of a TiN barrier layer and a W layer.

Referring to FIG. 5K, in the resultant of FIG. 5J, the second conductive layer 272 may be etched back to form a plurality of conductive landing pads LP in the cell array region MCA, and in the peripheral circuit region CORE/PERI, an upper surface of the intaglio insulating pattern 270P may be exposed.

In the cell array region MCA, the plurality of conductive landing pads LP may contact upper surfaces of each of the plurality of first recess contact plugs 262R while filling the plurality of recess spaces URS (see FIG. 5G) and the plurality of cutoff spaces COS (see FIG. 5I). Upper surfaces of the plurality of conductive landing pads LP may be closer to the substrate 210 than upper surfaces of the intaglio insulating patterns 270P. Accordingly, after the plurality of conductive landing pads LP are formed, a portion of the intaglio insulating pattern 270P may protrude above the plurality of conductive landing pads LP.

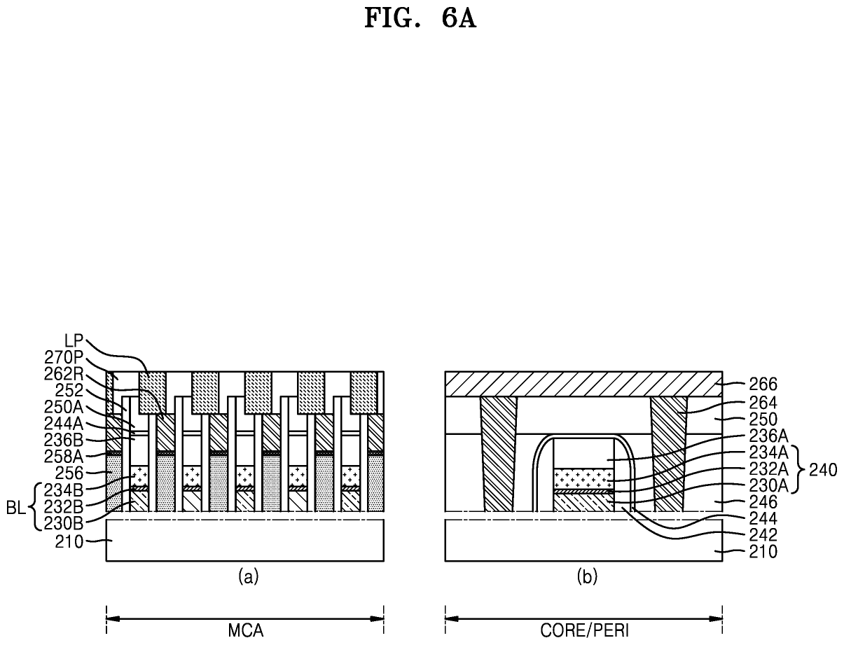

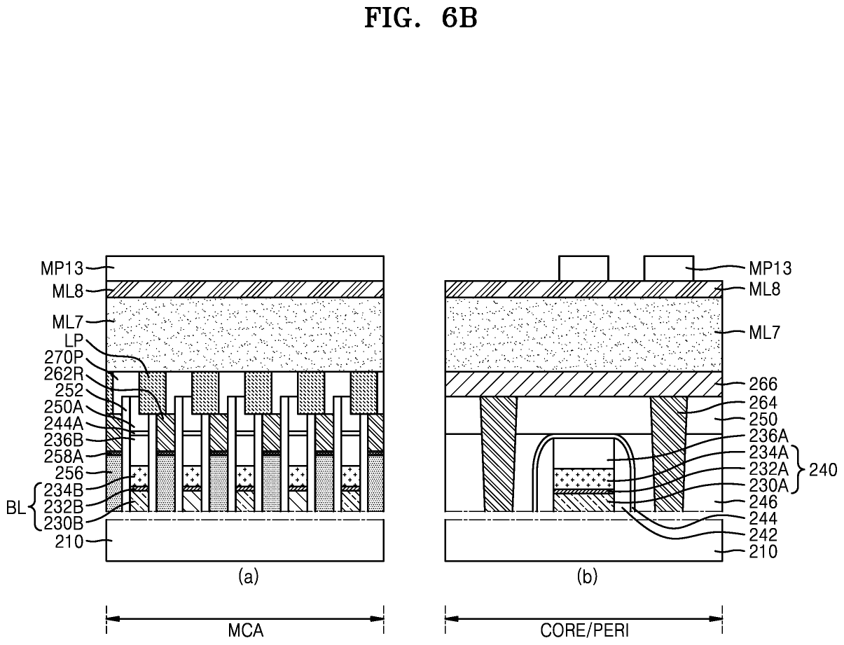

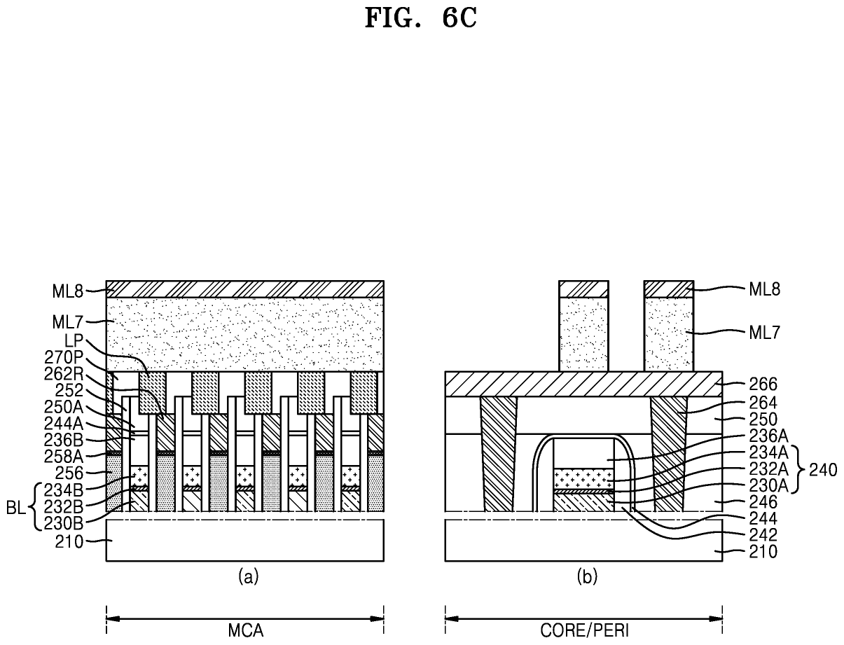

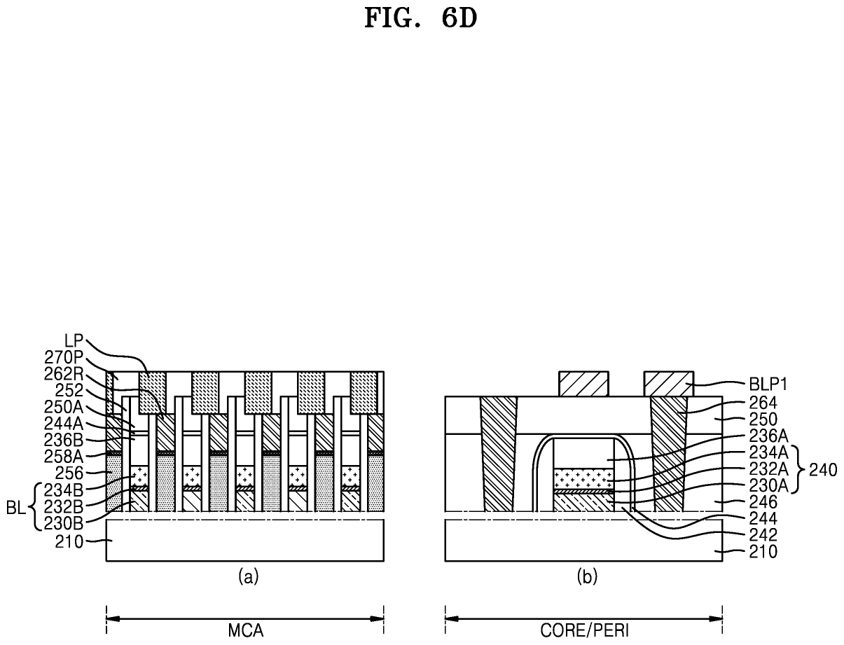

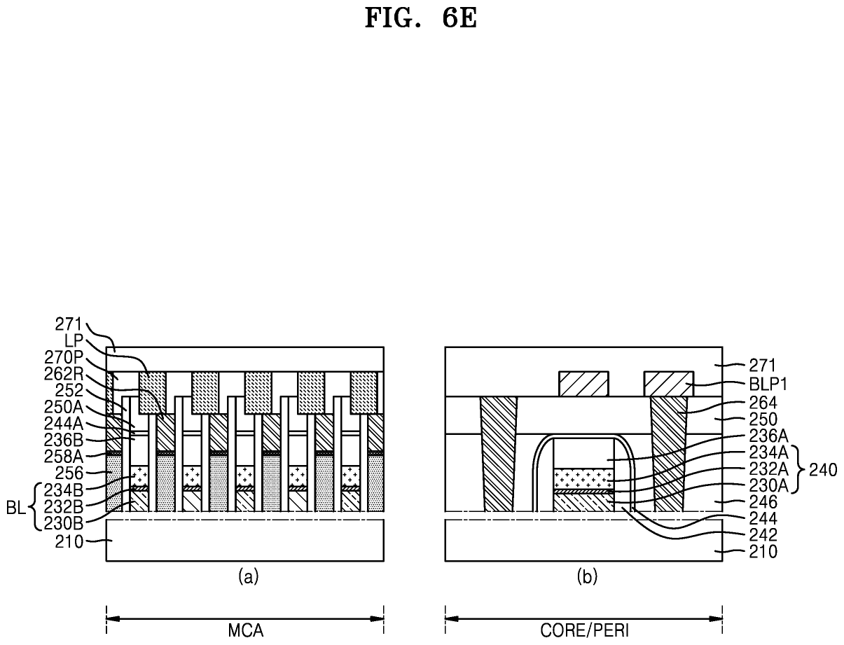

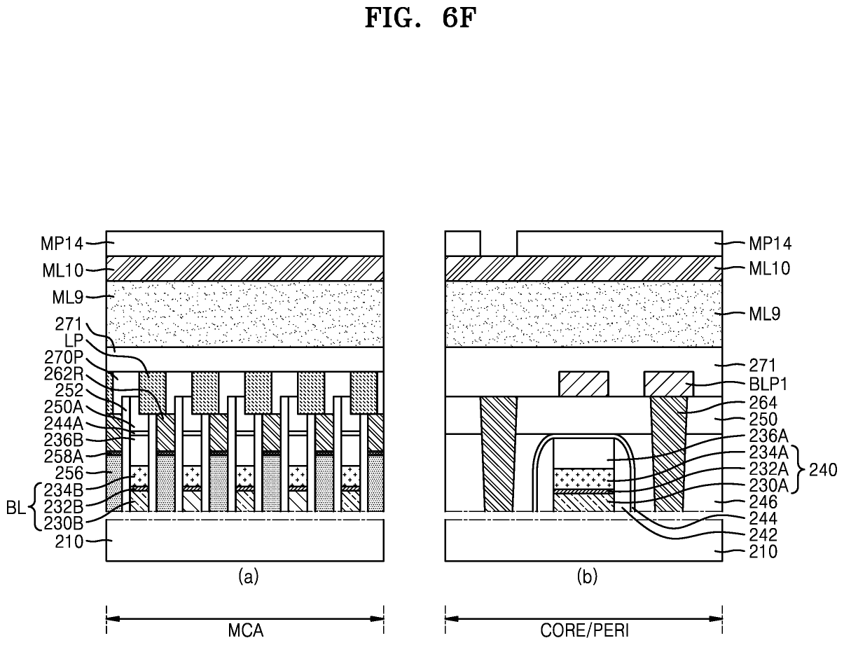

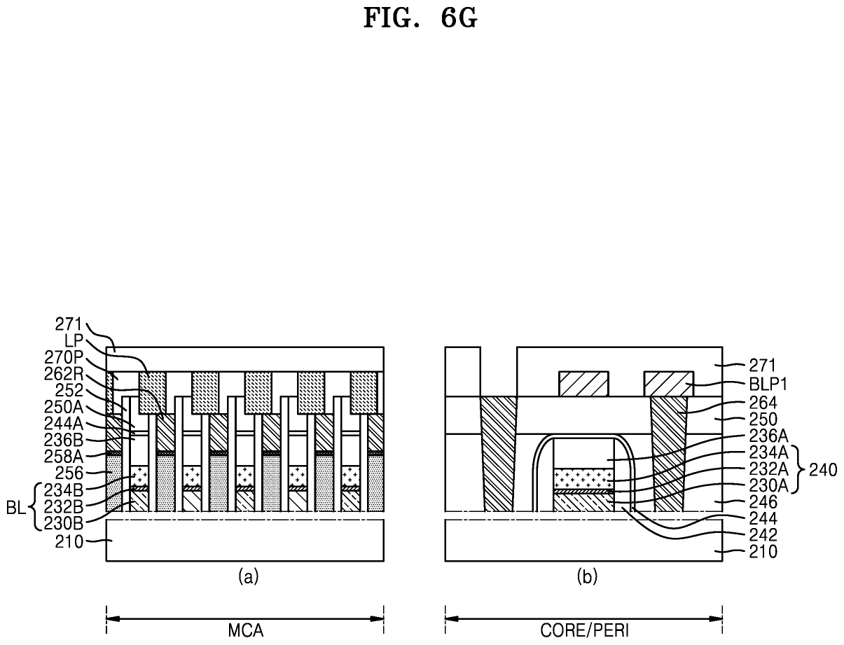

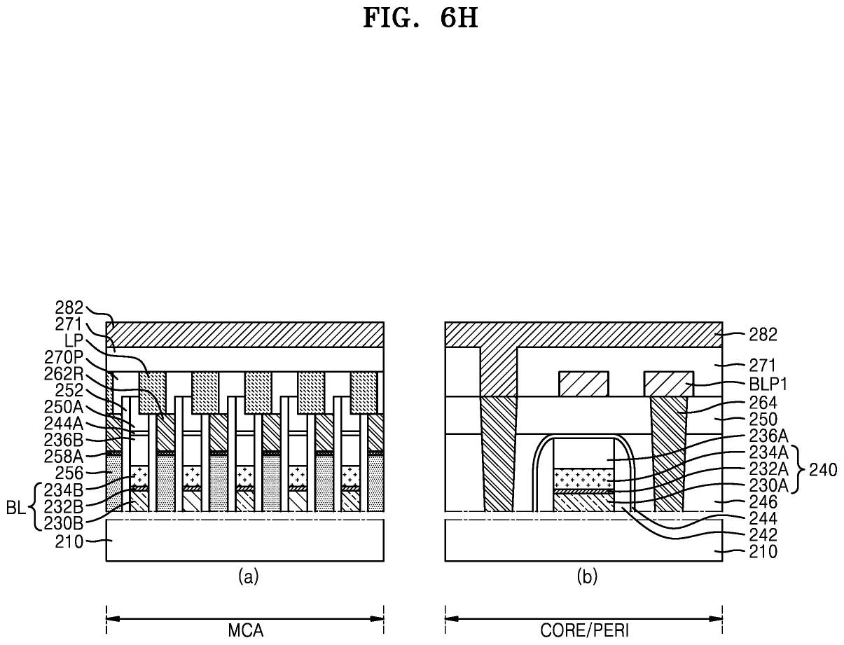

Next, with reference to FIGS. 6A to 6H, methods of manufacturing an integrated circuit device, according to the inventive concept will be described in sequence with specific examples. A process of FIGS. 6A to 6H may include a process of forming a first peripheral circuit wiring pattern BLP1. The process of forming a first peripheral circuit wiring pattern BLP1 may include forming a plurality of first peripheral circuit wiring patterns BLP1. The first peripheral circuit wiring patterns may extend laterally in a plane (e.g., a lower surface of the first peripheral circuit wiring patterns may extend on a plane defined by upper surfaces of each of the plurality of second contact plugs 264 and the upper insulating capping layer 250 in the peripheral circuit region CORE/PERI may be planarized to extend on the same plane) and may be spaced apart from each other.

Referring to FIG. 6A, by removing a portion of the intaglio insulating pattern 270P in the cell array region MCA and the peripheral circuit region CORE/PERI, uppermost surfaces of the intaglio insulating pattern 270P and the plurality of conductive landing pads LP may be at the same vertical level in the cell array region MCA and an upper surface of the first conductive layer 266 may be exposed in the peripheral circuit region CORE/PERI.

Referring to FIG. 6B, a seventh mask layer ML7 and an eighth mask layer ML8 sequentially covering the first conductive layer 266 and a photoresist pattern MP13 covering the eighth mask layer ML8 may be formed in the cell array region MCA and the peripheral circuit region CORE/PERI.

In embodiments, the seventh mask layer ML7 may include an ACL, and the eighth mask layer ML8 may include a SiON layer, but is not limited thereto. The photoresist pattern MP13 may be obtained from a resist layer for extreme ultraviolet (EUV), a resist layer for a KrF excimer laser, a resist layer for an ArF excimer laser, or a resist layer for an F2 excimer laser.

In embodiments, the photoresist pattern MP13 may be obtained from the resist layer for EUV. For example, in a state in which the resist layer for EUV is exposed in the cell array region MCA and the peripheral circuit region CORE/PERI, the photoresist pattern MP13 may be formed by exposing the resist layer for EUV with an EUV light source and developing the exposed resist layer for EUV only in the peripheral circuit region CORE/PERI among the cell array region MCA and the peripheral circuit region CORE/PERI.

Referring to FIG. 6C, in the resultant of FIG. 6B, the seventh mask layer ML7 and the eighth mask layer ML8 may be sequentially etched using the photoresist pattern MP13 as an etch mask, and then referring to FIG. 6D, the first conductive layer 266 may be patterned using the result obtained as an etch mask, to form the first peripheral circuit wiring pattern BLP1. A lower surface of the first peripheral circuit wiring pattern BLP1 may be at the same vertical level as an upper surface of the first contact plug 262. The first peripheral circuit wiring pattern BLP1 may have a plurality of first peripheral circuit wiring pattern recesses in locations where the first conductive layer 266 is removed during etching.

Some of the first peripheral circuit wiring patterns BLP1 may be connected to the plurality of second contact plugs 264. After the first peripheral circuit wiring pattern BLP1 is formed, unnecessary layers may be removed to expose upper surfaces of the plurality of landing pads LP and the intaglio insulating pattern 270P in the cell array region MCA and the first peripheral circuit wiring pattern BLP1 in the peripheral circuit region CORE/PERI, respectively.

Referring to FIGS. 6E and 6F, an insulating layer 271 that fills a space between each of the first peripheral circuit wiring patterns BLP1 in the peripheral circuit region CORE/PERI and that is disposed on the landing pads LP and the intaglio insulating pattern 270P in the cell array region MCA may be formed, and then a ninth mask layer ML9 that covers the first peripheral circuit wiring patterns BLP1 and the insulating layer 271, a tenth mask layer ML10, and a photoresist pattern MP14 may be sequentially formed. The insulating layer 271 may include a silicon nitride layer. The insulating layer 271 may be a wiring insulating layer in the peripheral circuit region CORE/PERI. The wiring insulating layer may be formed such that an upper surface of the first peripheral circuit wiring pattern BLP1 is not physically exposed to an external surface of the integrated circuit device.

In embodiments, the ninth mask layer ML9 may include an ACL, and the tenth mask layer ML10 may include a SiON layer, but is not limited thereto. The photoresist pattern MP14 may be obtained from a resist layer for a KrF excimer laser, a resist layer for an ArF excimer laser, or a resist layer for an F2 excimer laser.

Referring to FIG. 6G, at least a portion of the insulating layer 271 formed in the peripheral circuit region CORE/PERI may be patterned using a photolithography process until an upper surface of some of the plurality of second contact plugs 264 is exposed.

Referring to FIG. 6H, a third conductive layer 282 may be formed on the resultant of FIG. 6G. The third conductive layer 282 may fill a space (see FIG. 6G) where the upper surface of the second contact plug 264 is exposed by etching a portion of the insulating layer 271 in the peripheral circuit region CORE/PERI, while contacting the exposed upper surface of the second contact plug 264.

The third conductive layer 282 may be formed of and/or include metal, conductive metal nitride, or a combination thereof. In embodiments, the third conductive layer 282 may be formed of and/or include TiN, W, or a combination thereof. In an example, the third conductive layer 282 may include only a TiN layer. In another example, the third conductive layer 282 may include a stacked structure of a TiN barrier layer and a W layer.

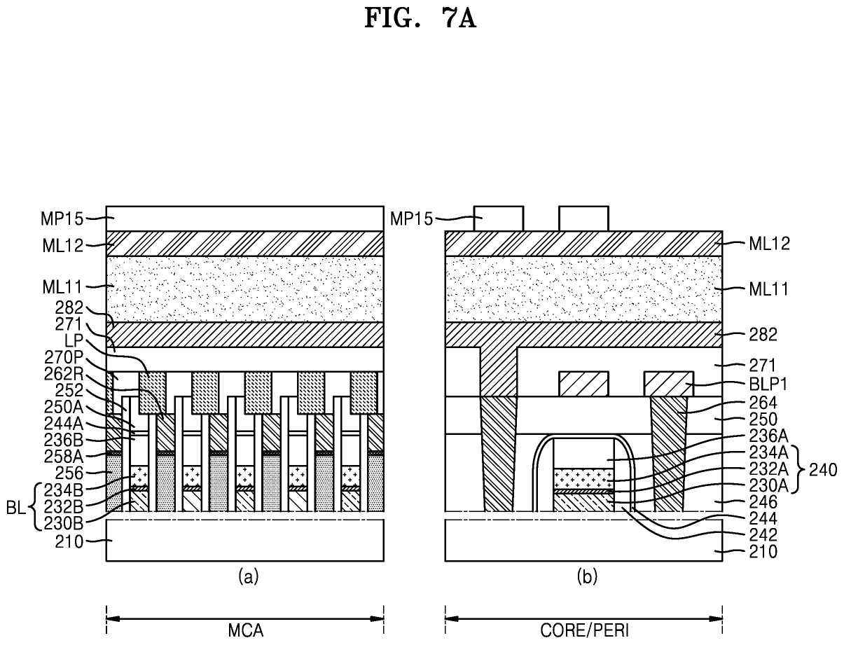

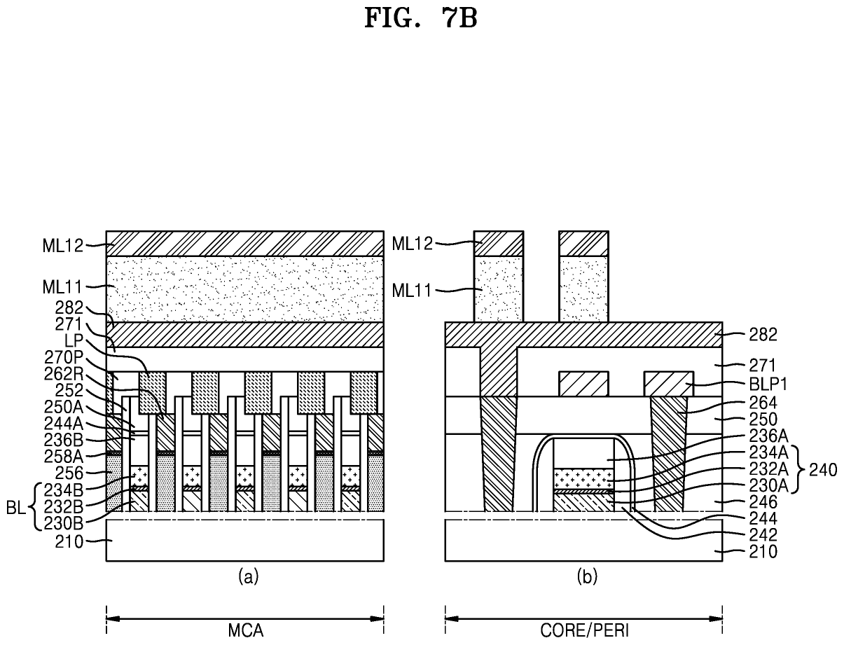

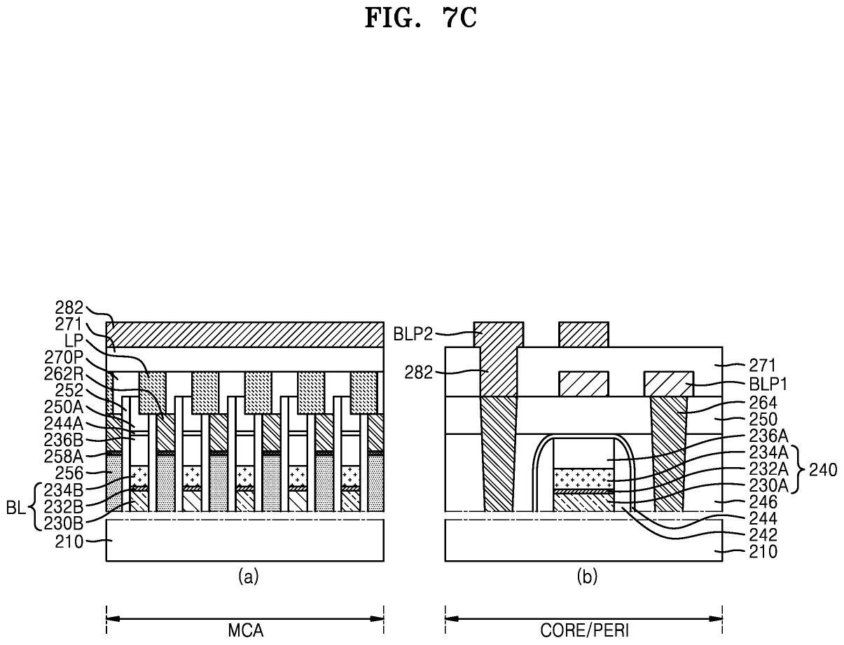

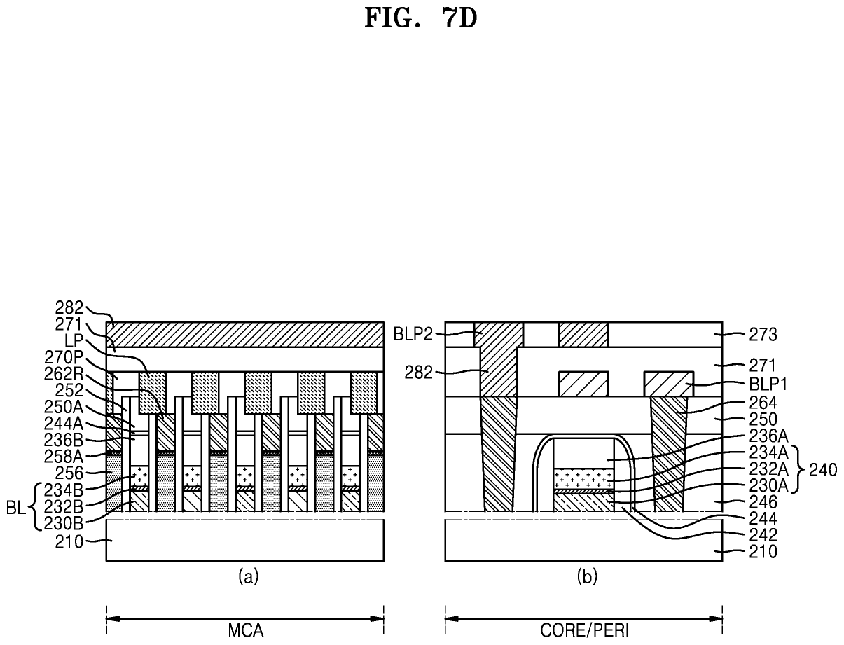

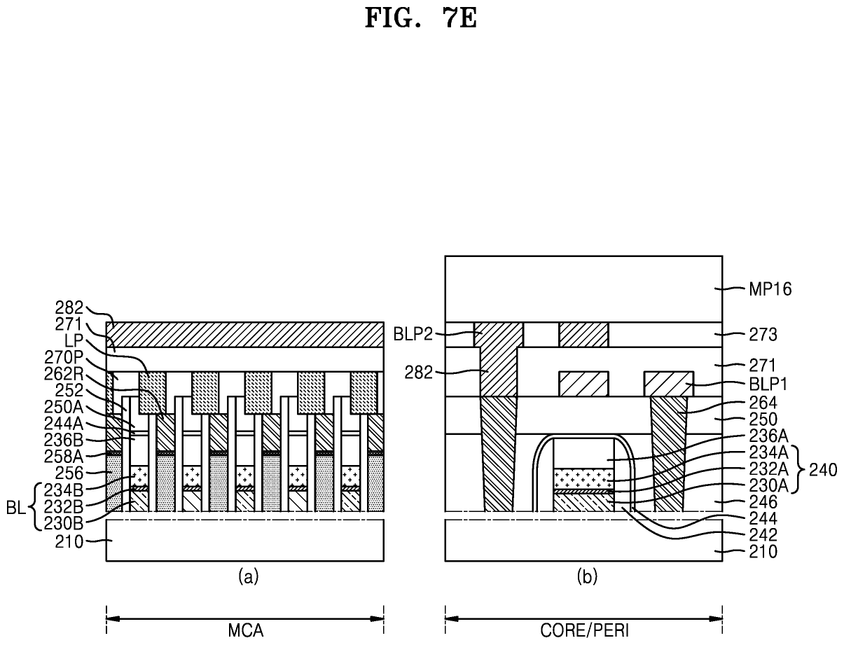

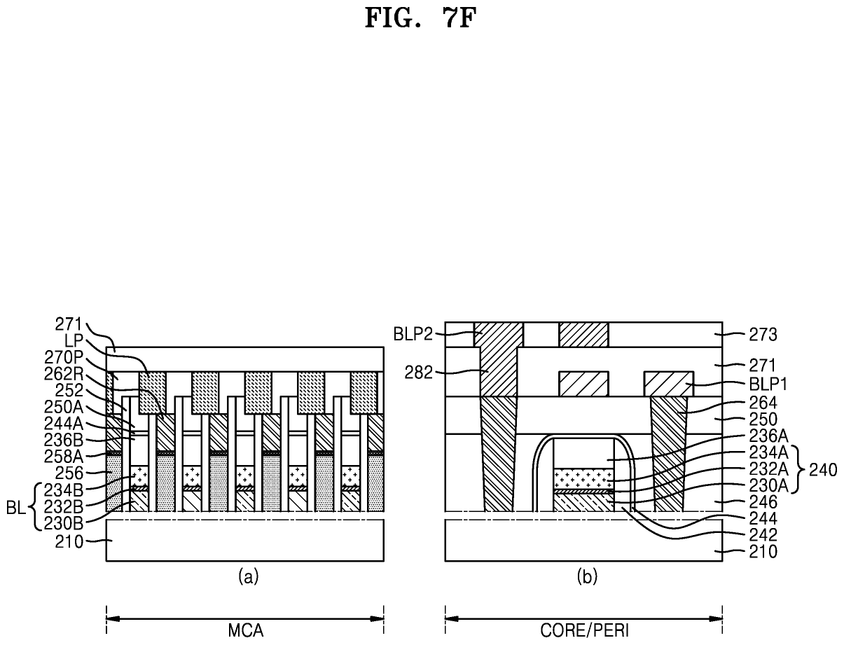

Next, with reference to FIGS. 7A to 7F, methods of manufacturing an integrated circuit device according to the inventive concept will be described in sequence with specific examples. A process of FIGS. 7A to 7F may include a process of forming a second peripheral circuit wiring pattern BLP21.

Referring to FIG. 7A, an eleventh mask layer ML11 and a twelfth mask layer ML12 sequentially covering the third conductive layer 282, and a photoresist pattern MP15 may be formed in the cell array region MCA and the peripheral circuit region CORE/PERI.

In embodiments, the eleventh mask layer ML11 may include an ACL, and the twelfth mask layer ML12 may include a SiON layer, but is not limited thereto. The photoresist pattern MP15 may be obtained from a resist layer for extreme ultraviolet (EUV), a resist layer for a KrF excimer laser, a resist layer for an ArF excimer laser, or a resist layer for an F2 excimer laser.

In embodiments, the photoresist pattern MP15 may be obtained from the resist layer for EUV. For example, in a state in which the resist layer for EUV is exposed in the cell array region MCA and the peripheral circuit region CORE/PERI, the photoresist pattern MP15 may be formed by exposing the resist layer for EUV with an EUV light source and developing the exposed resist layer for EUV only in the peripheral circuit region CORE/PERI among the cell array region MCA and the peripheral circuit region CORE/PERI.

Referring to FIG. 7B, in the resultant of FIG. 7A, the eleventh mask layer ML11 and the twelfth mask layer ML12 may be sequentially etched using the photoresist pattern MP15 as an etch mask, and then referring to FIG. 7C, the third conductive layer 282 may be patterned using the result obtained as an etch mask, to form the second peripheral circuit wiring pattern BLP2. The process of forming the second peripheral circuit wiring pattern BLP2 may include forming a plurality of second peripheral circuit wiring patterns BLP2. The second peripheral circuit wiring patterns BLP2 may extend laterally in a plane and may be spaced apart from each other. The first peripheral circuit wiring patterns BLP1 may extend laterally in plane that is at a higher vertical level than the plane the second peripheral circuit wiring pattern BLP2 extends in. Portions of the second peripheral circuit wiring pattern BLP2 may form vias electrically connecting at least a portion of the second peripheral circuit wiring pattern BLP2 to a second contact plug 264 extending through the insulating structure 273.

Some of the second peripheral circuit wiring patterns BLP2 may be connected to the plurality of second contact plugs 264. After the second peripheral circuit wiring pattern BLP2 is formed, unnecessary layers may be removed to expose upper surfaces of the third conductive layer 282 in the cell array region MCA and the second peripheral circuit wiring pattern BLP2 in the peripheral circuit region CORE/PERI, respectively.

Referring to FIG. 7D, an insulating structure 273, which may be an insulating layer (e.g., a layer of insulating material), may be formed to fill a space between each of the second peripheral circuit wiring patterns BLP2 in the peripheral circuit region CORE/PERI. In this case, an upper surface of the insulating structure 273 may be coplanar with an upper surface of the second peripheral circuit wiring pattern BLP2.

Referring to FIGS. 7E and 7F, a photoresist pattern MP16 may be formed on the upper surfaces of the second peripheral circuit wiring pattern BLP2 and the insulating structure 273 in the peripheral circuit region CORE/PERI (see FIG. 7E), and then the third conductive layer 282 in the cell array region MCA may be etched using the photoresist pattern MP16 as an etch mask. Through the above processes, the peripheral circuit wiring patterns BLP1 and BLP2 having a two-layer structure may be formed. After the removal of the third conductive layer 282 in the cell array region MCA, the vertical level, as measured relative to the main surface 210M of the substrate 210, of the uppermost surface of the peripheral circuit region CORE/PERI may be greater than the vertical level, as measured relative to the main surface 210M of the substrate 210, of the uppermost surface of the cell array region MCA.

In this case, the second peripheral circuit wiring pattern BLP2 may be formed to have the same thickness as the first peripheral circuit wiring pattern BLP1, and a vertical level of the uppermost surface of the first peripheral circuit wiring pattern BLP1 may be lower than a vertical level of the lowermost surface of the second peripheral circuit wiring pattern BLP2. The second peripheral circuit wiring pattern BLP2 may be formed of and/or include the same material as the first peripheral circuit wiring pattern BLP1.

Herein, a case where the first peripheral circuit wiring pattern BLP1 is formed on the peripheral circuit region CORE/PERI after forming the landing pad LP on the cell array region MCA has been described, the inventive concept is not limited thereto. After first forming the first peripheral circuit wiring pattern BLP1 on the peripheral circuit region CORE/PERI, the landing pad LP may be formed in the cell array region MCA.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate comprising a cell region and a peripheral circuit region;
a plurality of bit line structures spaced apart from each other in the cell region with each bit line structure comprising a bit line conductive layer and a bit line capping layer on the bit line conductive layer; and
a plurality of landing pads with each landing pad of the plurality of landing pads disposed on a respective bit line structure of the plurality of bit line structures and electrically connected to the respective bit line structure,
wherein the peripheral circuit region comprises a gate structure and a core capping layer on the gate structure;
a direct contact plug extending vertically with respect to the substrate;
first peripheral circuit wiring patterns extending laterally and spaced apart from each other on a first plane at a first vertical level relative to the substrate; and
second peripheral circuit wiring patterns extending laterally and spaced apart from each other on a second plane at a second vertical level relative to the substrate, wherein the second vertical level is different from the first vertical level.

2. The integrated circuit device according to claim 1, wherein the first plane and the second plane are each parallel to the substrate.

3. The integrated circuit device according to claim 1, wherein a height of the second vertical level is greater than a height of the first vertical level.

4. The integrated circuit device according to claim 1, wherein the first vertical level is at the same vertical level as the plurality of landing pads relative to a main surface of the substrate.

5. The integrated circuit device according to claim 1, further comprising an insulating material separating the first peripheral circuit wiring patterns from the second peripheral circuit wiring patterns.

6. The integrated circuit device according to claim 5, further comprising an insulating layer on the plurality of landing pads, wherein:
the insulating layer is formed of silicon nitride; and
the second peripheral circuit wiring patterns are formed of the same material as the first peripheral circuit wiring patterns.

7. The integrated circuit device according to claim 1, wherein at least a portion of at least one of the first peripheral circuit wiring patterns is electrically connected to the direct contact plug.

8. The integrated circuit device according to claim 7, wherein a lower surface of the first peripheral circuit wiring pattern is at the same vertical level as an upper surface of the direct contact plug.

9. The integrated circuit device according to claim 1, further comprising a via electrically connecting at least a portion of the second peripheral circuit wiring patterns to the direct contact plug.

10. The integrated circuit device according to claim 1, wherein a height of the uppermost surface of the peripheral circuit region is greater than a height of the uppermost surface of the cell region.

11. The integrated circuit device according to claim 10, wherein a difference between the height of the uppermost surface of the peripheral circuit region and the height of the uppermost surface of the cell region is the same as the thickness of the second peripheral circuit wiring patterns.

12. An integrated circuit device comprising:
a substrate comprising a cell region and a peripheral circuit region;
a plurality of bit line structures extending parallel to each other in a first horizontal direction in the cell region;
a plurality of buried contacts electrically connected to the cell region with each buried contact of the plurality of buried contacts filling a portion of a space between respective adjacent bit line structures of the plurality of bit line structures;
a plurality of landing pads with each landing pad of the plurality of landing pads disposed on a respective buried contact of the plurality of buried contacts;
a gate structure and a direct contact plug that are arranged in the peripheral circuit region;
a first peripheral circuit wiring pattern at a vertical level that is higher relative to the substrate than an uppermost surface of the gate structure and having a plurality of first peripheral circuit wiring pattern recesses;
an insulating layer filling the plurality of first peripheral circuit wiring pattern recesses and covering an upper portion of the first peripheral circuit wiring pattern; and
a second peripheral circuit wiring pattern formed on the insulating layer.

13. The integrated circuit device according to claim 12, wherein at least a portion of the first peripheral circuit wiring pattern is electrically connected to the direct contact plug.

14. The integrated circuit device according to claim 13, wherein a lower surface of the first peripheral circuit wiring pattern is at the same vertical level as an upper surface of the direct contact plug.

15. The integrated circuit device according to claim 12, further comprising a via electrically connecting at least a portion of the second peripheral circuit wiring pattern to the direct contact plug.

16. The integrated circuit device according to claim 12, further comprising a plurality of capacitor structures, each comprising a lower electrode electrically connected to a respective landing pad of the plurality of landing pads, an upper electrode, and a capacitor dielectric layer interposed between the lower electrode and the upper electrode.

17. The integrated circuit device according to claim 12, wherein an upper surface of the first peripheral circuit wiring pattern is at the same vertical level as an upper surface of the plurality of landing pads relative to a main surface of the substrate.

18. An integrated circuit device comprising:
a substrate comprising a cell region having a first active region and a peripheral circuit region having a second active region;
a direct contact contacting the first active region in the cell region;
a bit line structure on the direct contact;
a capacitor structure electrically connected to the first active region;
a gate structure on the second active region in the peripheral circuit region;
a first peripheral circuit wiring pattern adjacent to the gate structure and electrically connected to the second active region;
a second peripheral circuit wiring pattern on the first peripheral circuit wiring pattern;
a wiring insulating layer between the first peripheral circuit wiring pattern and the second peripheral circuit wiring pattern; and
a contact plug penetrating the wiring insulating layer and connected to at least one of the first peripheral circuit wiring pattern and the second peripheral circuit wiring pattern,
wherein the wiring insulating layer extends into the cell region, and
the capacitor structure comprises a dummy electrode that contacts an upper surface of the wiring insulating layer.

19. The integrated circuit device according to claim 18, wherein:
a vertical level of an uppermost surface of the first peripheral circuit wiring pattern is lower than a vertical level of a lowermost surface of the second peripheral circuit wiring pattern relative to the substrate, and
the second peripheral circuit wiring pattern is formed of the same material as the first peripheral circuit wiring pattern.

20. The integrated circuit device according to claim 18, wherein the wiring insulating layer is formed such that an upper surface of the first peripheral circuit wiring pattern is not physically exposed to an external surface of the integrated circuit device.
